(19) United States
(12) Patent Application Publication
(10) Pub. No.: US 2010/0309061 A1
(43) Pub. Date: Dec. 9, 2010

(54) A MICRO ANTENNA DEVICE

(76) Inventor: Dhiraj Sinha, Cambridge (GB)

Correspondence Address: HESLIN ROTHENBERG FARLEY & MESITI PC, 5 COLUMBIA CIRCLE, ALBANY, NY, 12203, US

(21) Appl. No.: 12/809,780

(22) PCT Filed: Nov. 12, 2008
(86) PCT No.: PCT/GB08/03800

§ 371 Date: Aug. 19, 2010

(30) Foreign Application Priority Data
Dec. 20, 2007 (GB) 0724788.5
Apr. 23, 2008 (GB) 0807346.2

(51) Int. Cl. H01Q 1/38; H01L 41/083

(52) U.S. Cl. 343/700 MS; 310/366

(57) ABSTRACT

An ultra small antenna made of a piezoelectric material is provided. The wavelength of radio signals propagating through the piezoelectric material is shortened because of its high dielectric constant and a resonance between the radio signal and the modes of its mechanical waves at various frequencies results in high amplitude signals in the transmission and reception mode.

### FIELD OF THE INVENTION

The present invention relates to devices using piezoelectric materials mainly for wireless telecommunication applications, specifically, but not exclusively, to an ultra small antenna using piezoelectric materials operating at a frequency of greater than 20 kHz.

### BACKGROUND OF THE INVENTION

Antennas are devices which convert time varying electrical current into electromagnetic waves and vice versa. They are essential aspects of communication systems and are connected to transceiver circuits of a wireless communication link. Antennas have not changed much over the past hundred years in terms of size or volume. A metallic structure in various forms transmits or receives radio wave under electrical resonance.

One of the major problems associated with antennas is that their dimensions must be comparable to the wavelength of electromagnetic waves which they transmit or receive. The wavelength of electromagnetic waves used in communication system varies from fraction of a metre for television application to several kilometres for amplitude modulated radio broadcasts. This implies that antennas cannot be miniaturised using conventional technology and their integration on an electronic chip is one of the greatest challenges of electrical engineering.

In a typical mobile handset, antennas cover around 15 to 25 percent of the total space. In a TV, the antenna can be as big as the TV set in terms of size.

Previously, researchers have thought that the only way to reduce antennas would be to reduce the wavelength of communication. Reducing the wavelength of radiation for wireless communication is impossible as it would mean using Terahertz radiation where the attenuation is very high.

Developments in the field of miniaturised antennas have failed to catch up with electronics industry which was revolutionised by the invention of integrated circuits which started a trend of manufacturing smaller, cheaper and faster devices.

A piezoelectric resonator is an elastic solid body consisting of a piezoelectric crystalline material which can be excited to mechanical resonance under an electric field. As the crystal vibrates, the periodic deformation causes periodic piezoelectric charges on the metallic electrodes linked to it.

An antenna based on piezoelectric materials was disclosed by Politekhnicesky (GB 1499033 A). Similar disclosures were made by Duan (Chinese Patent CN 1107618) and Yifang (Chinese Patent CN 1564374 A). However, all these patent applications describe “bulk” or “surface acoustic waves”. The term ‘acoustic’ specifically denotes sound waves whose frequencies fall within the range from 20 Hz to 20 KHz. So, from a technological perspective, the above-referenced patent applications only discuss acoustic waves in piezoelectric materials which can work for the acoustic frequency range of 20 Hz to 20 KHz.

Normal communication system mainly uses frequencies which are much above the acoustic range. For example, the Very High Frequency (VHF) range varies from 30 to 300 MHz and the Ultra High Frequency (UHF) range, which is used in TV and mobile communication varies from 300 MHz to 3 GHz. Mechanical waves corresponding to these frequencies can propagate through thin film piezoelectric materials and are usually termed Rayleigh-Lamb waves. In the case of bulk piezoelectric materials, these waves are simply called bulk mechanical waves.

Although, commercial organisations have adopted the term Surface Acoustic Wave (SAW) to mean devices which operate on mechanical waves or Rayleigh-Lamb waves, the scientific literature viz. the research papers and patent applications explicitly state the exact scientific terminology associated with such kind of waves. That is that prior art SAW devices which discuss reception and transmission of radio waves, only operate at acoustic frequency ranges, not the normal radio waves above 20 KHz which are widely used in communication links. The prior art does not discuss the origin of these waves which is usually in the far field region in the transmission or reception mode.

### SUMMARY OF INVENTION

An important objective of the present invention is to provide a micro antenna device based on wireless radio frequency effects associated with a piezoelectric material, which overcomes, or at least reduces some of the above-mentioned problems of the prior art.

The transmission of radio signals in higher than acoustic frequencies into the far field region require significant amount of power. Similarly, reception of signal from the far field region would need a piezoelectric material which can pick up signal from the noise floor of an environment. These are important aspects of a practical communication system where the sources of transmission and reception are separated by long distances. The antenna's field pattern is dependent on the distance.

The present invention is on a novel way of detection of radio frequency magnetic fields using free standing microstructures mounted over, developed or coupled to piezoelectric material. The radio frequency magnetic field results in induction of a radio frequency voltage in the piezoelectric material, which is set in mechanical vibration. The mechanical vibration within the piezoelectric material is subsequently transferred to the microstructures mounted over it resulting in high amplitude vibration under resonance, which is measured by an optical detection or an electrical system. The high quality factor associated with the vibrations of the free standing microstructure demonstrates a convincing way of developing microantennas, which could be potentially integrated with electronic components on an electronic chip.

Accordingly, in a first aspect, the invention provides a device for use in a wireless telecommunications network as a transmit antenna, the device comprising a piezoelectric material, wherein when a time varying electrical excitation at frequencies greater than 20 kHz is applied to the piezoelectric material, this results in the emission of radio waves into free space at the said frequencies.

According to a second aspect, the invention provides a device for use in a wireless telecommunications network as a receive antenna, the device comprising a piezoelectric material in thin film or bulk form, wherein when a radio wave in free space at a frequency greater than 20 kHz is applied to the material, this results in an electrical excitation in the material at the said frequencies.

According to a third aspect, the invention provides a method of reception of electromagnetic waves where the impedance of the piezoelectric material is matched to that of free space using an impedance matching circuit comprising a set of shunt (or series) inductors and a set of series (or shunt) capacitors in such a manner that the products of space and piezoelectric impedances match the products of the impedances of series (or shunt) capacitors and shunt (or series) and inductors.

According to a fourth aspect, the invention provides a method of applying a filter to transmitted or received electromagnetic waves wherein the filtering is achieved by the resonant frequency of the antenna substantially limiting the passage of electromagnetic waves close in frequency to the resonant frequency of the antenna.

According to a fifth aspect, the invention provides a nuclear magnetic resonance spectroscopy or magnetic resonance imaging apparatus where the static magnetic field is generated by metallic coils having DC currents and radio frequency waves are generated by using piezoelectric materials where the wired time varying electrical excitation applied to the piezoelectric material results in acceleration of charges within the material leading to emission of radio frequency waves; a receiver for the said magnetic resonance spectroscopy or magnetic resonance imaging apparatus where the radio frequency waves emitted by the particular sample are received by piezoelectric materials in such a manner that the radio frequency waves hitting the piezoelectric material accelerate the charges within the material resulting in displacement current which induces voltage in the said piezoelectric material.

According to a sixth aspect, the invention provides a nuclear quadrupole resonance detection apparatus where the radio frequency waves are generated by using piezoelectric materials where the wired time varying electrical excitation applied to the piezoelectric material results in acceleration of charges within the material leading to emission of radio frequency waves; a receiver for the said nuclear quadrupole resonance detection apparatus where the radio frequency waves emitted by the particular sample are received by piezoelectric materials in such a manner that the radio frequency waves hitting the piezoelectric material accelerate the charges within the material resulting in displacement current which induces voltage in the said piezoelectric material.

According to a seventh aspect, the invention provides a device for detection of radio signals where the signals are being radiated by objects in outer space like pulsars.

Embodiments of the invention will now be more fully described, by way of example, with reference to the drawings, of which:

FIG. 1 shows a piezoelectric stack connected to a signal generator, according to one embodiment of the present invention;

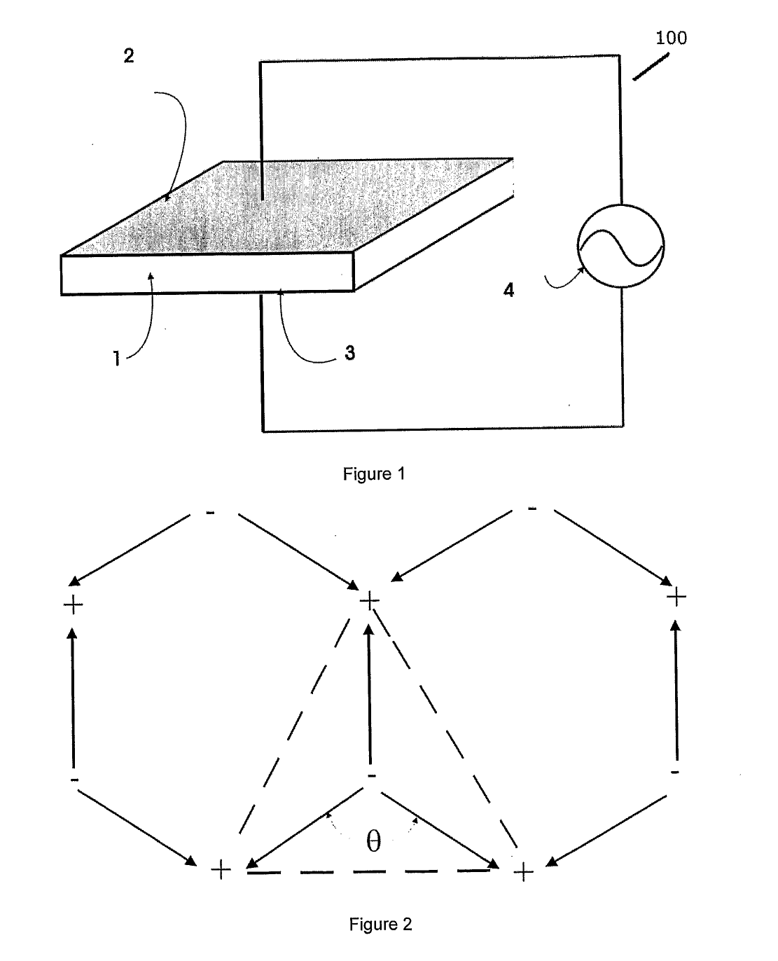

FIG. 2 shows the molecular layout of a typical piezoelectric material as is known in the field of the invention;

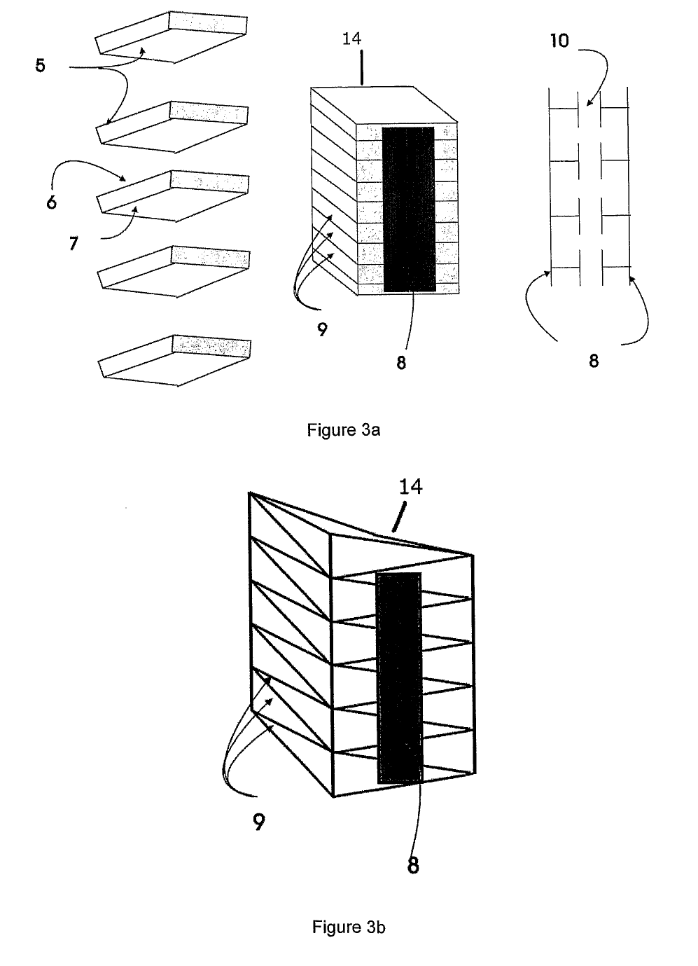

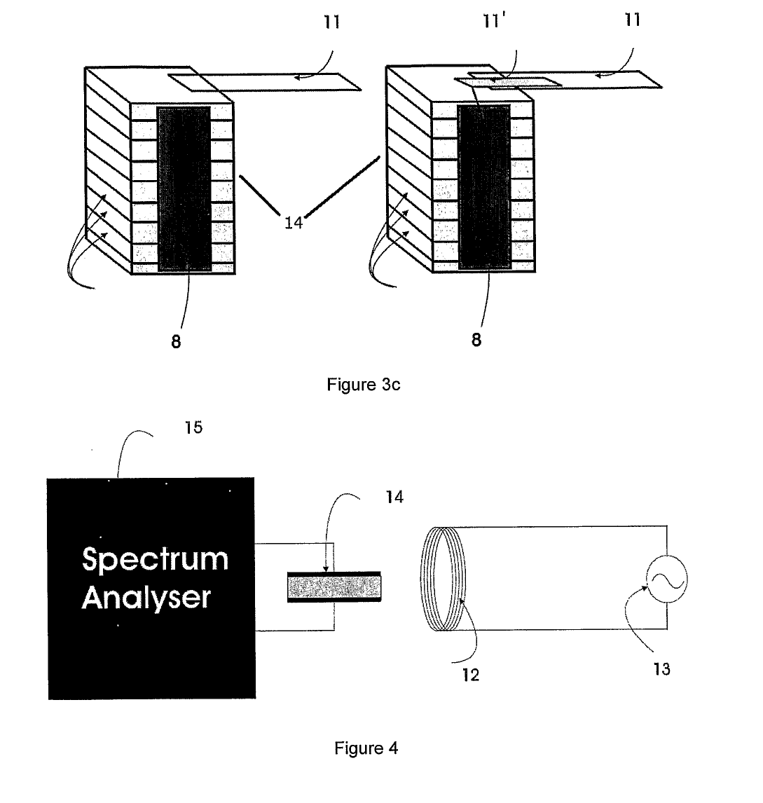

FIG. 3a shows the internal structural details of multi-layered a piezoelectric stack as is known in the field of the invention;

FIG. 3b shows a multi-layered piezoelectric stack with tapering layers, according to a second embodiment of the present invention;

FIG. 3c shows a multi-layered piezoelectric stack with a microcantilever mounted over it, according to a third embodiment of the present invention;

FIG. 4 shows an experimental set up for detecting wireless radio frequency signal using a piezoelectric material, according to a fourth embodiment of the present invention;

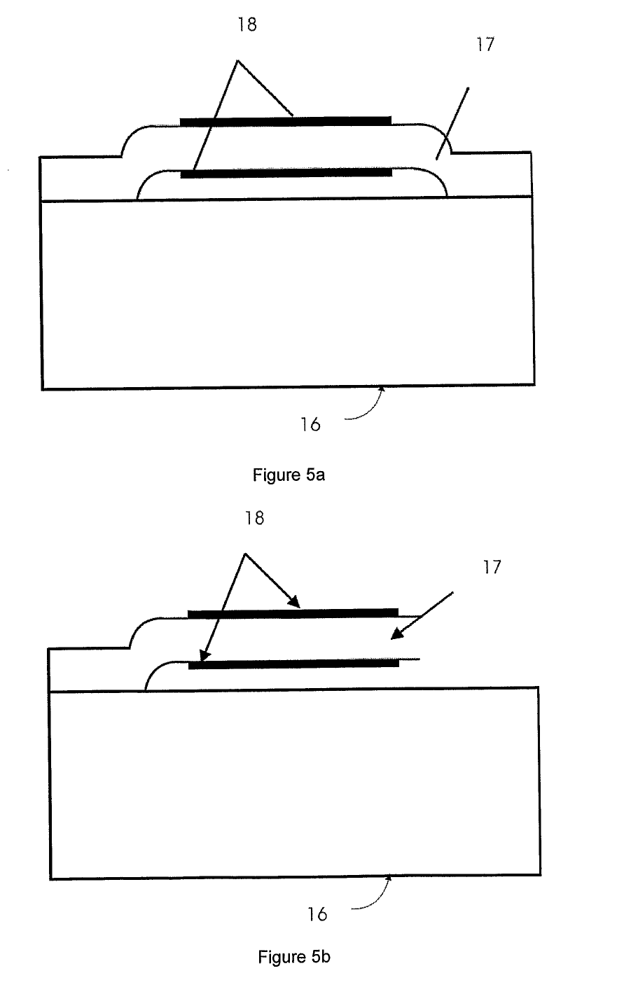

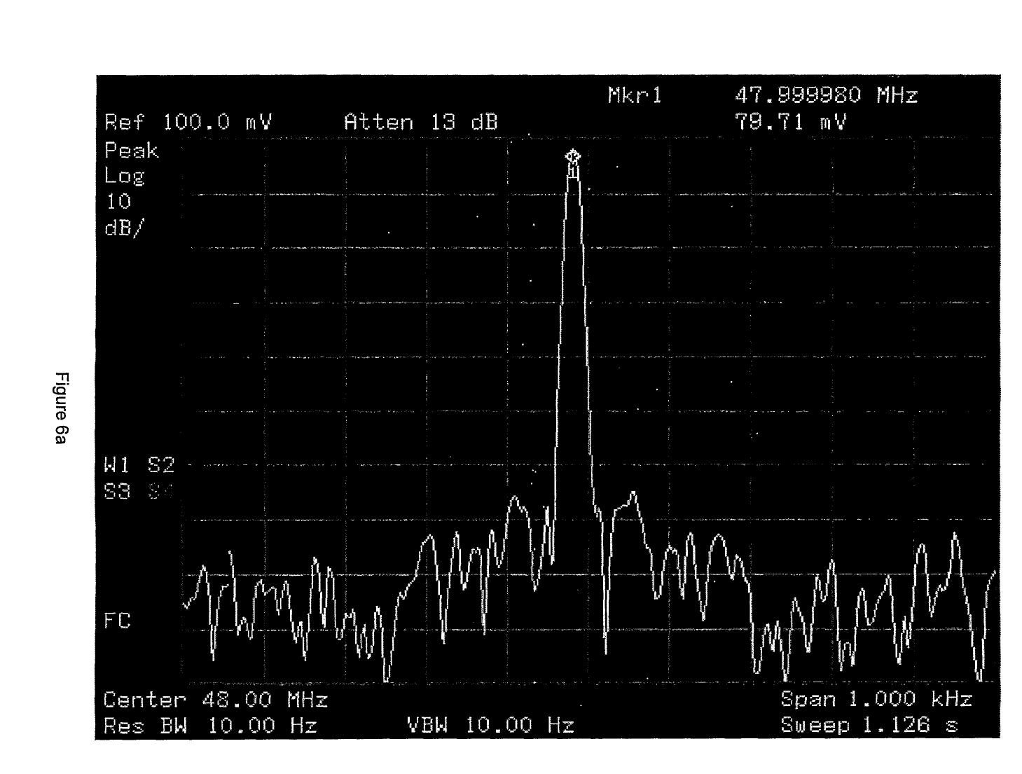

FIG. 5a shows a piezoelectric material in the form of a beam;

FIG. 5b shows a piezoelectric material in the form of a cantilever;

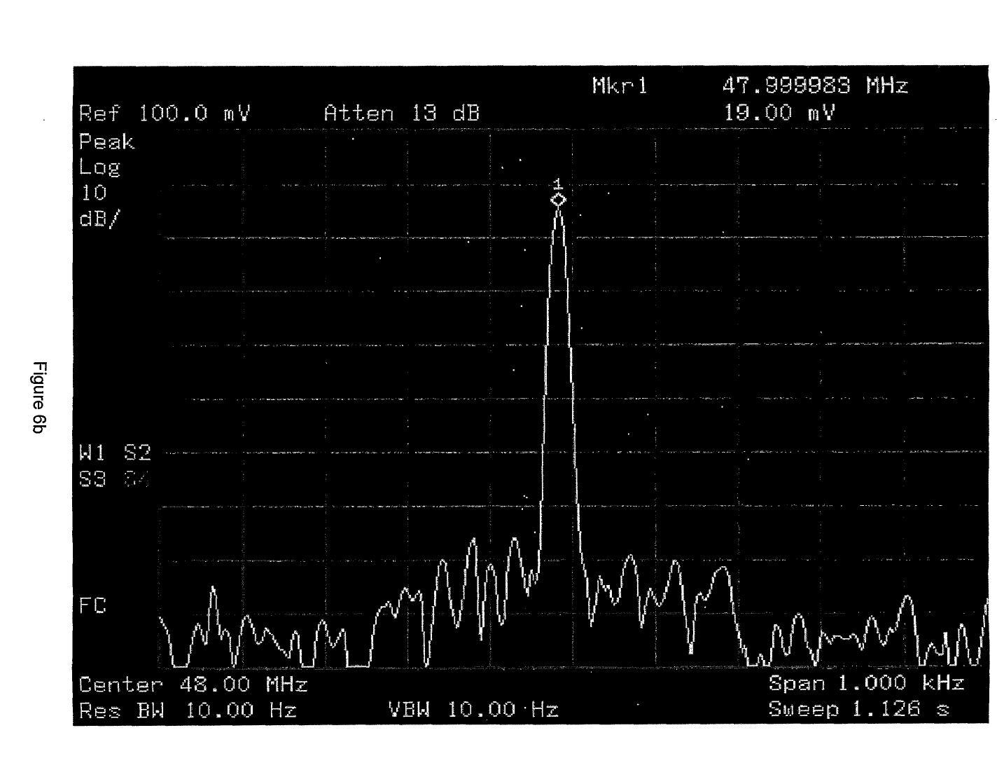

FIG. 6a shows a typical result of a piezoelectric material as a receiver;

FIG. 6b shows a typical result of a piezoelectric material as a transmitter;

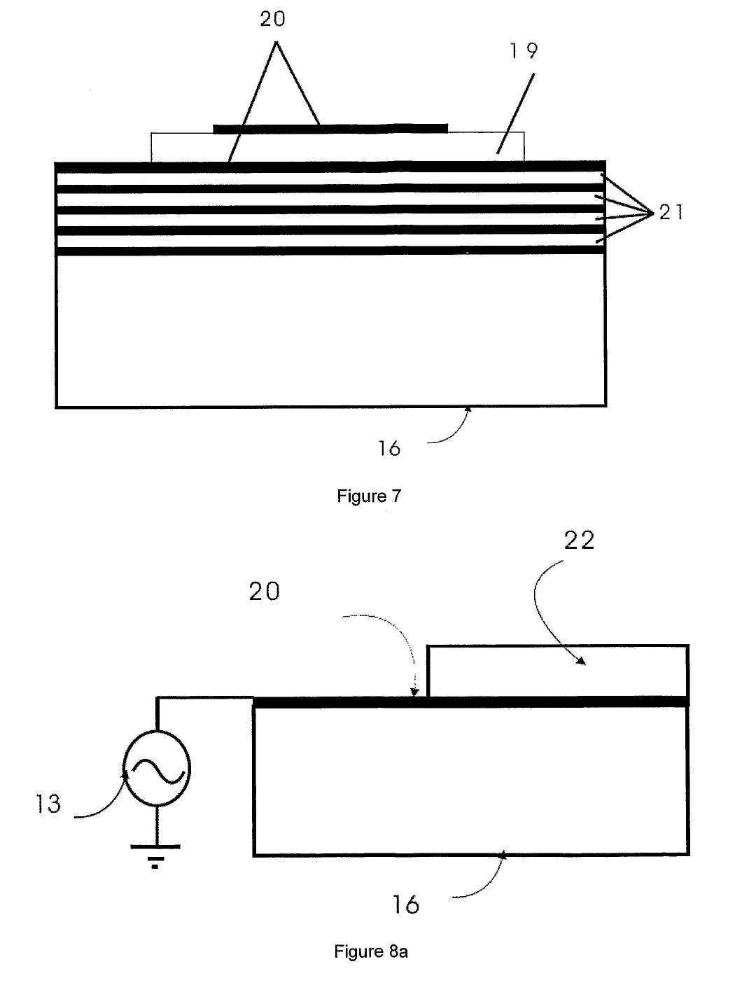

FIG. 7 shows a bulk piezoelectric material with an array of reflectors;

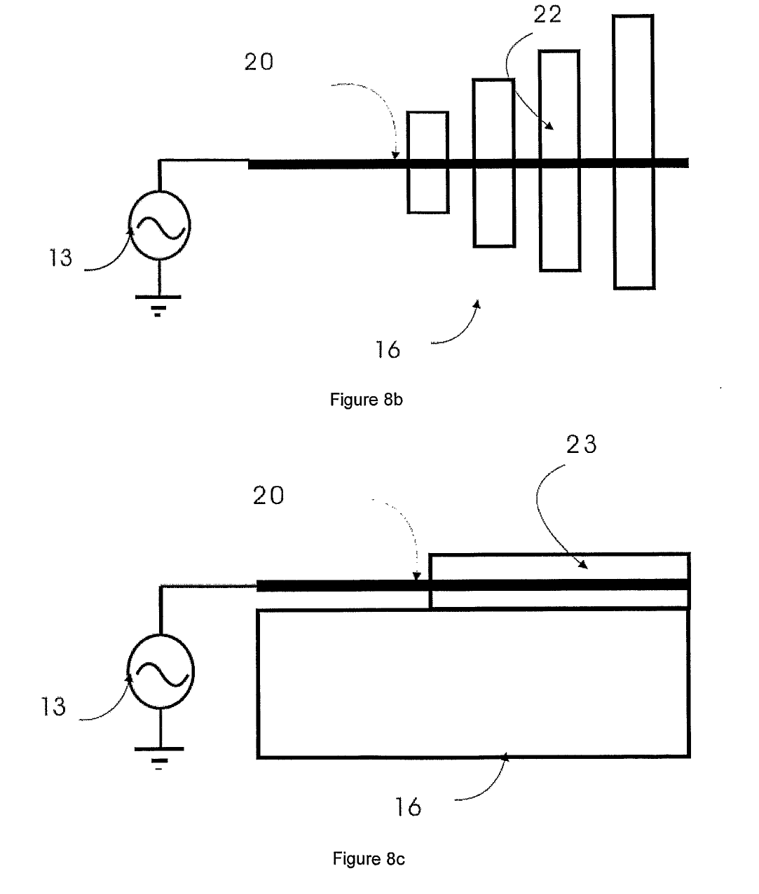

FIG. 8a shows a bulk piezoelectric resonator excited by a voltage source;

FIG. 8b shows an array of bulk piezoelectric resonators excited by a voltage source;

FIG. 8c shows a bulk piezoelectric resonator with an electrode implanted within it;

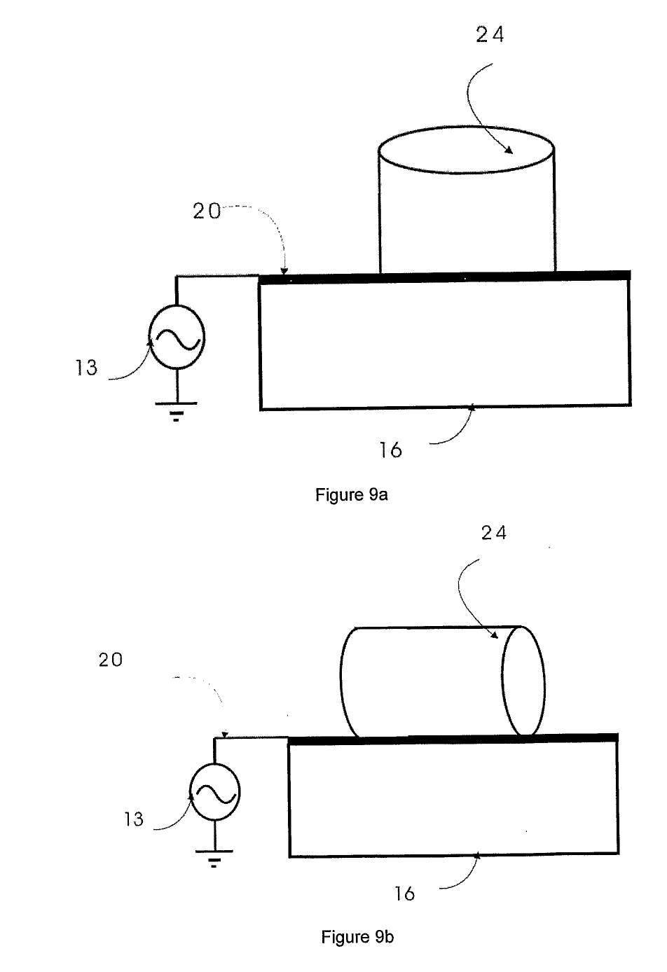

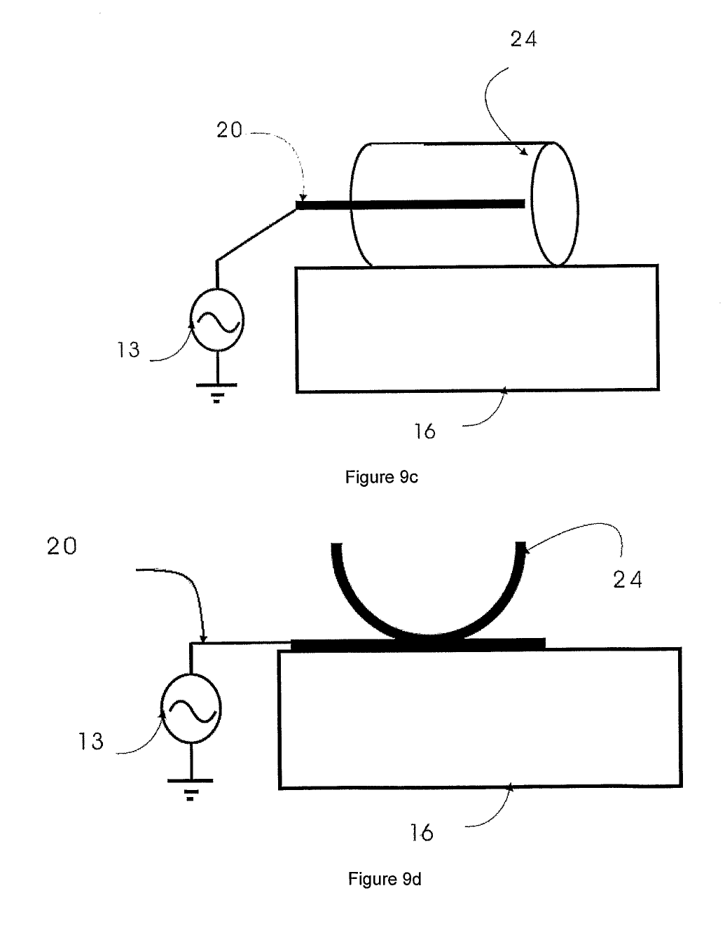

FIGS. 9a, 9b and 9c show a cylindrical shaped piezoelectric resonator excited by electrodes at different points;

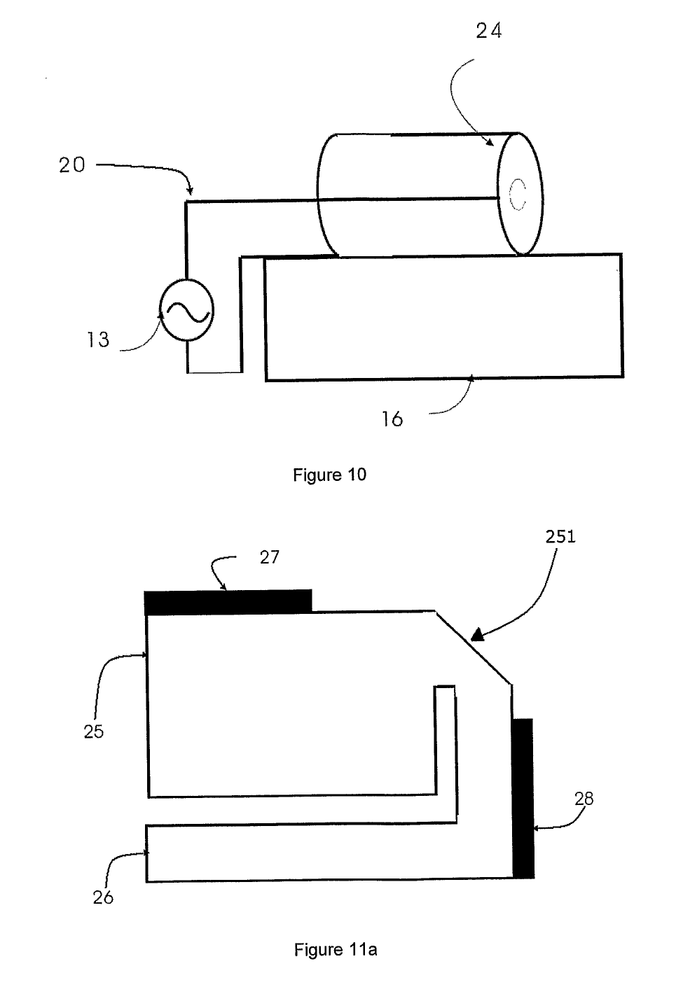

FIG. 10 shows a disc shaped piezoelectric material;

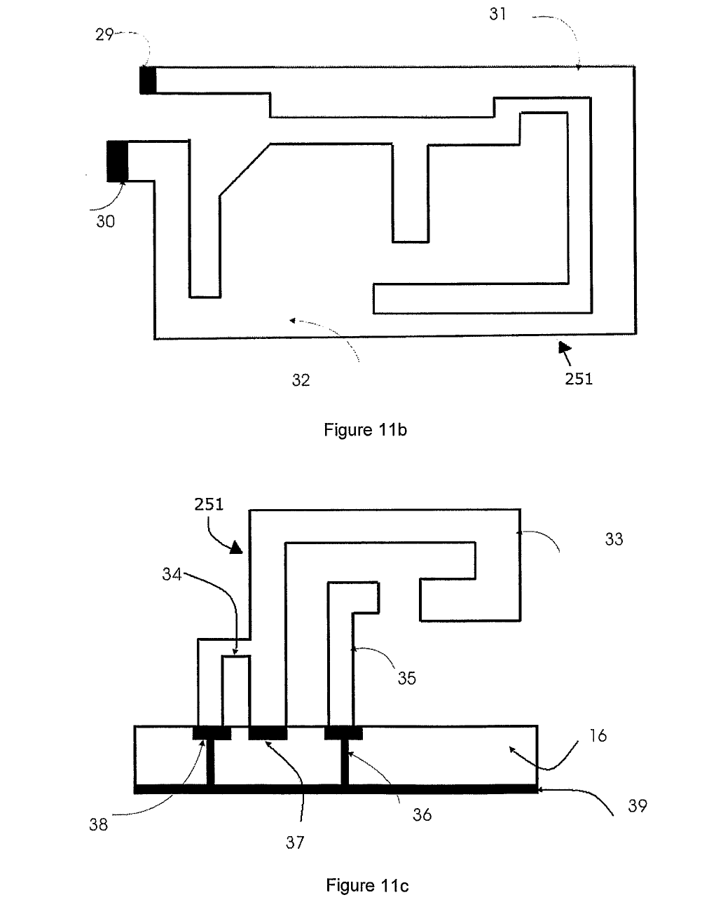

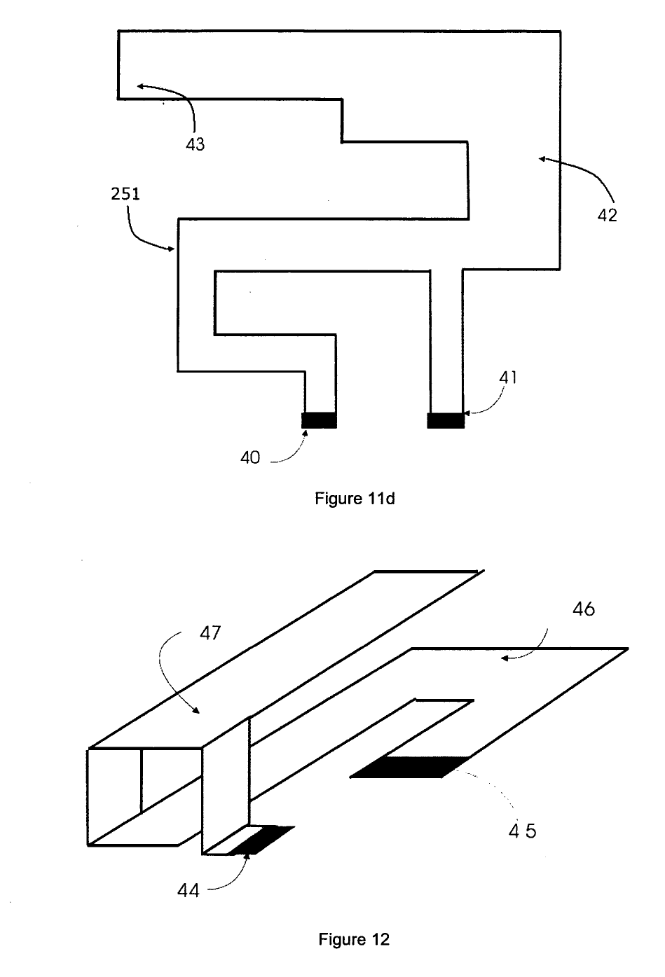

FIGS. 11a, 11b, 11c and 11d show planar piezoelectric resonators with different patch sections and electrodes;

FIGS. 11a, 11b, 11c and 11d show planar piezoelectric resonators with different patch sections and electrodes;

FIG. 12 shows a three dimensional piezoelectric resonators with different planar patch sections and electrodes;

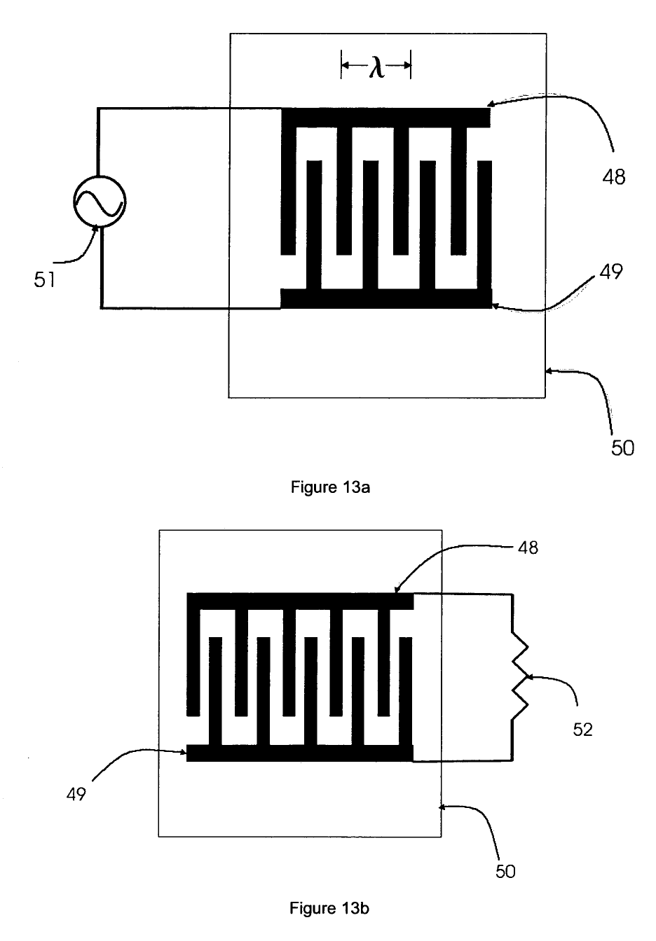

FIG. 13a shows a thin film piezoelectric resonator as a transmitter;

FIG. 13b shows a thin film piezoelectric resonator as a receiver;

FIG. 14a shows a typical result of a thin film piezoelectric resonator as a receiver;

FIG. 14b shows a typical result of a thin film piezoelectric resonator as a transmitter;

FIG. 14c shows a typical result of a multi-turn coil as a transmitter and a receiver;

FIG. 14d shows a piezoelectric resonator as a receiver over a frequency sweep;

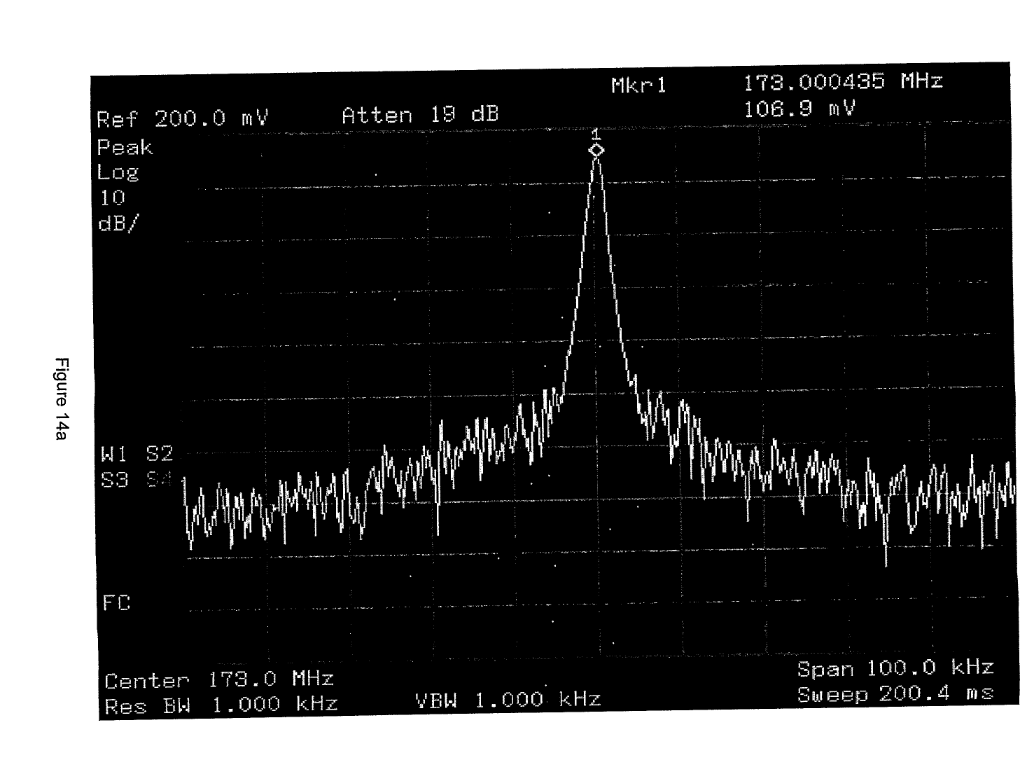

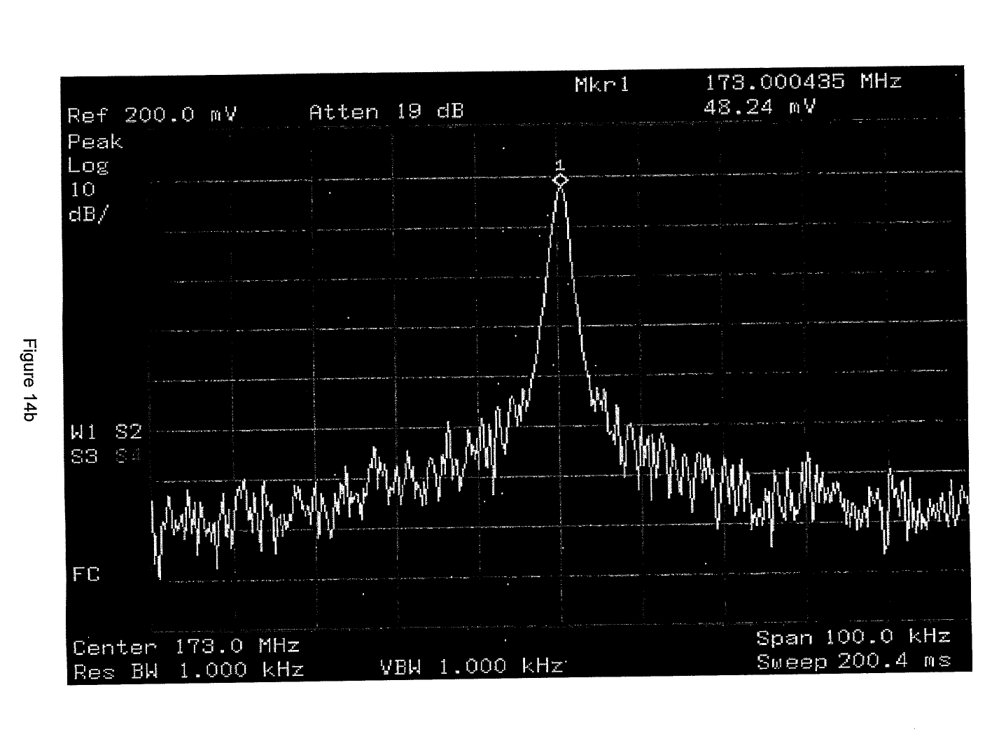

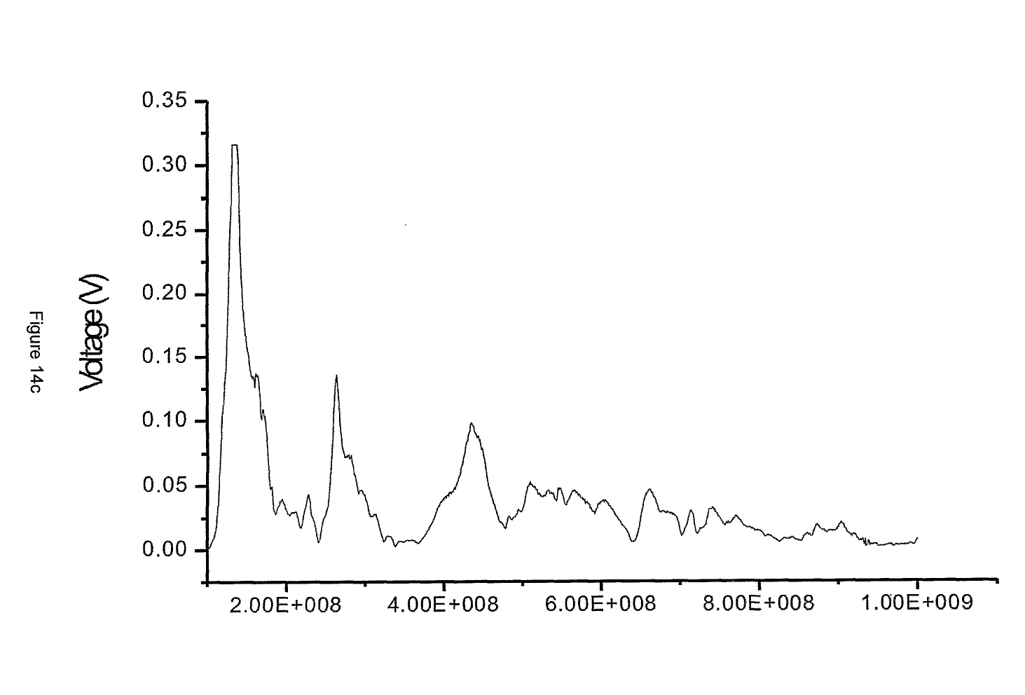

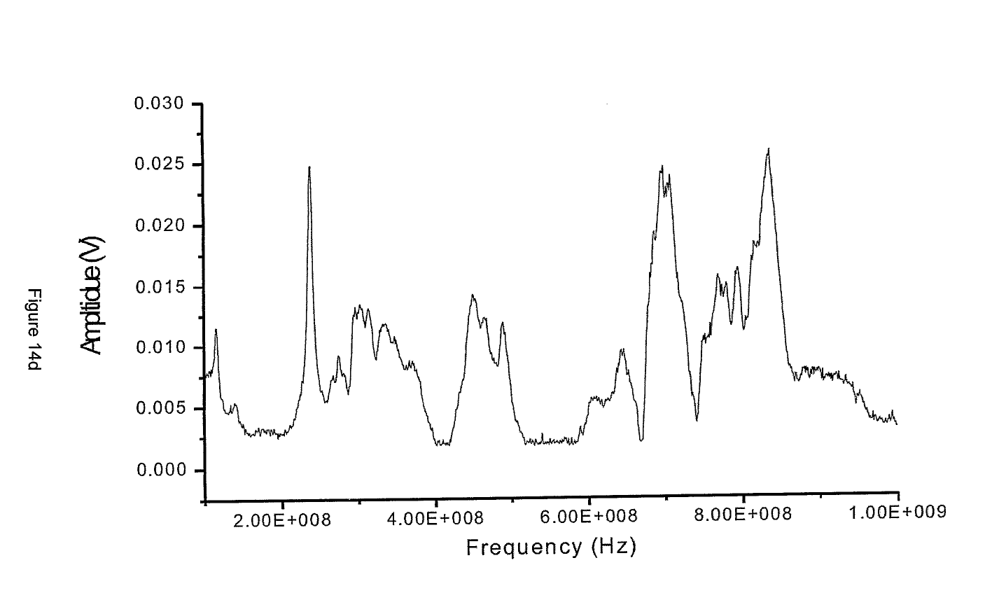

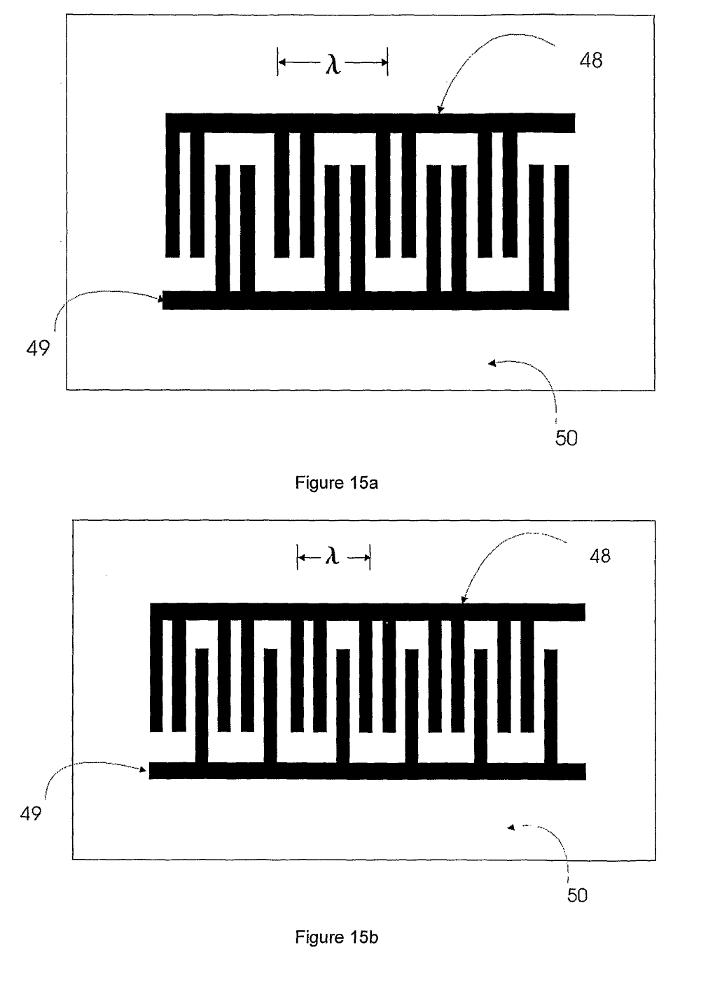

FIGS. 15a and 15b show a thin film piezoelectric resonator with multiple electrode fingers;

FIG. 15c shows a thin film piezoelectric resonator with reflectors;

FIG. 16a shows thin film piezoelectric resonators in ladder configuration;

FIG. 16b shows thin film piezoelectric resonators connected in parallel;

FIG. 16c shows a thin film piezoelectric resonator having electrode fingers along horizontal as well as vertical configuration.

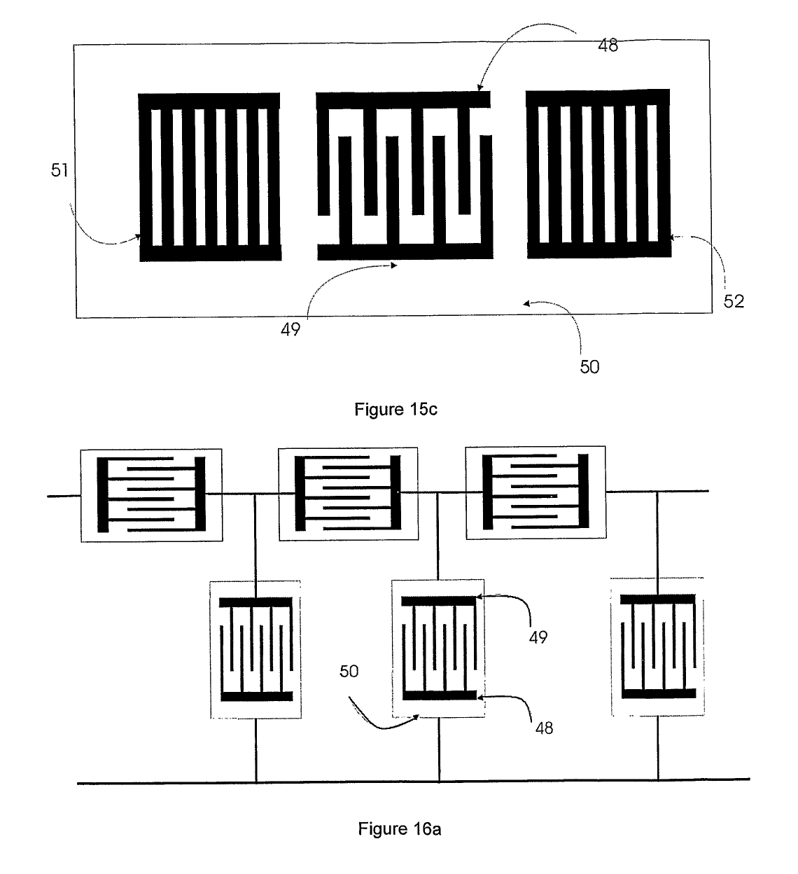

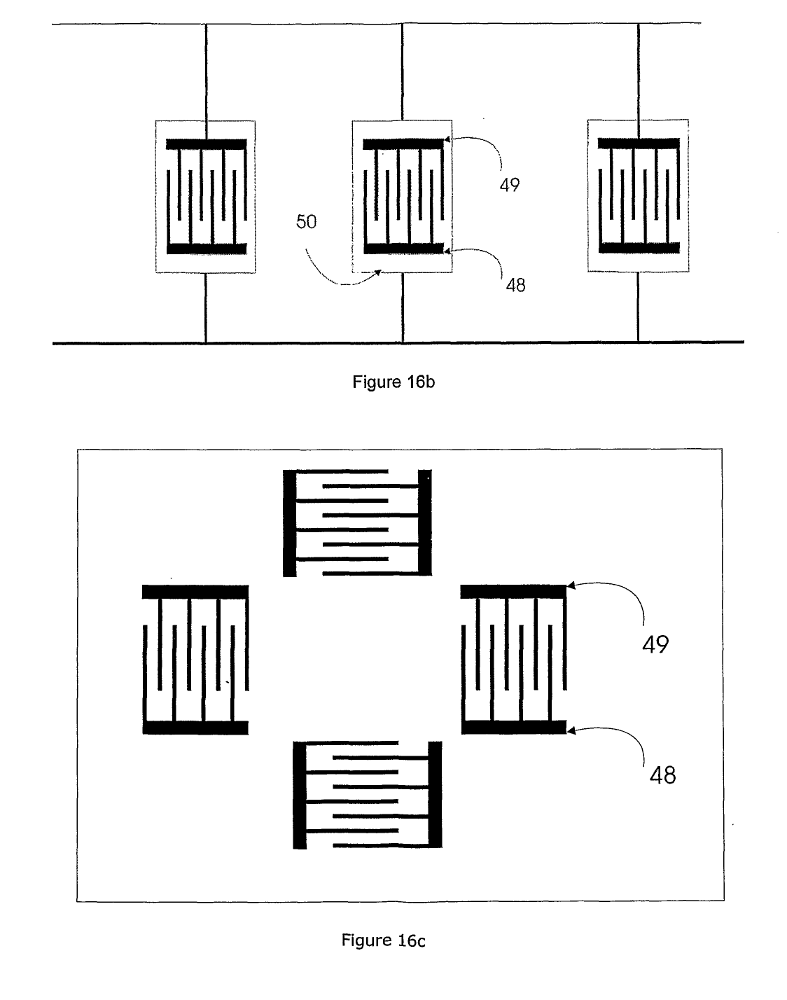

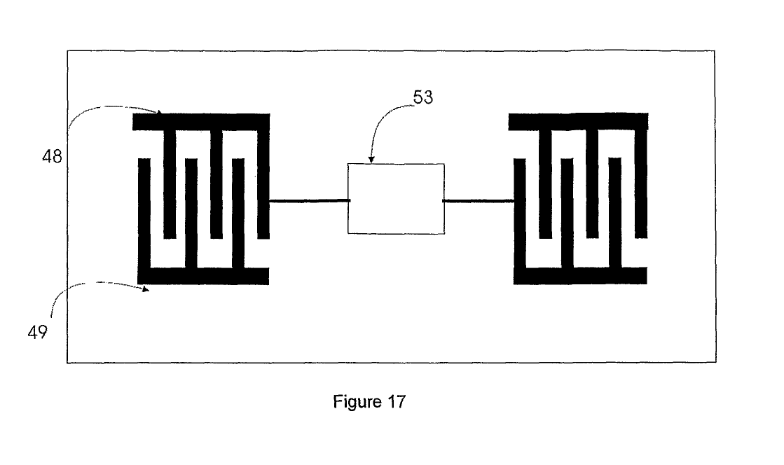

FIG. 17 shows two thin film piezoelectric resonators connected to a metal strip;

FIG. 18 shows thin film piezoelectric resonators with a Z shaped channel;

FIG. 19 shows thin film piezoelectric resonators with zig-zag shaped electrode fingers;

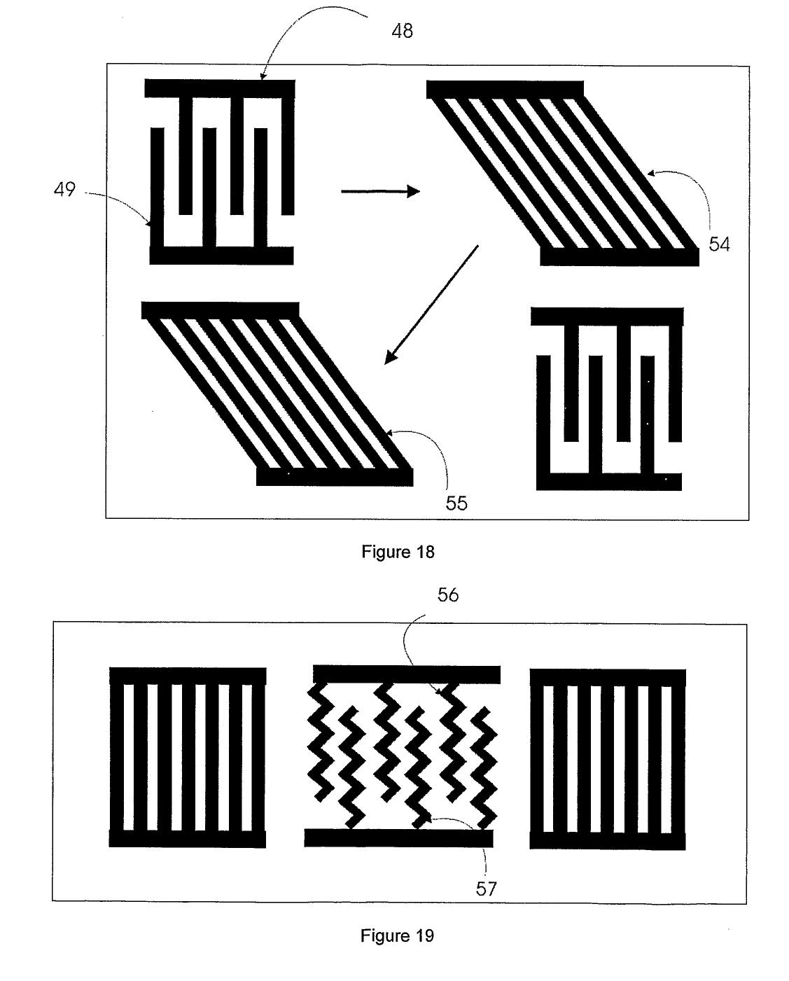

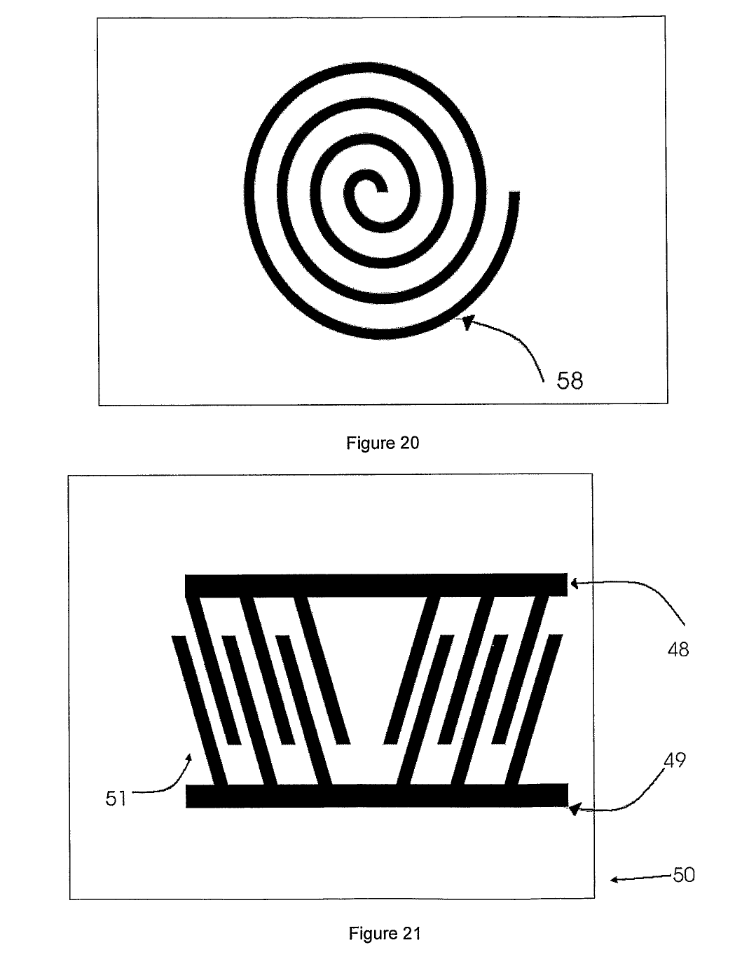

FIG. 20 shows thin film piezoelectric resonator with circular electrode;

FIG. 21 shows thin film piezoelectric resonators with slanted electrode fingers;

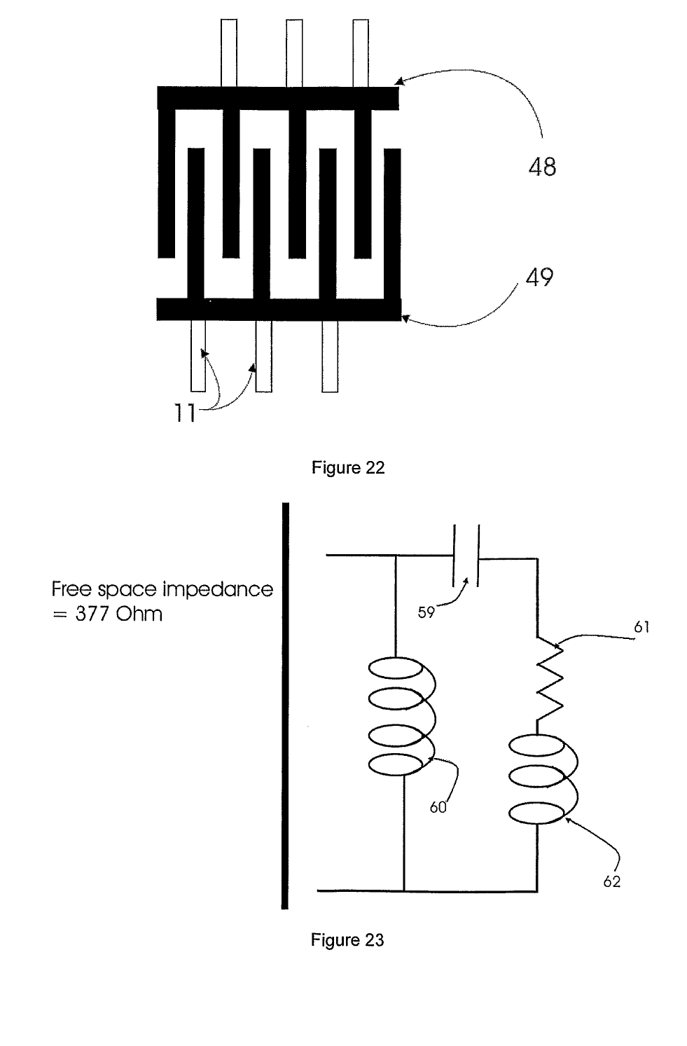

FIG. 22 shows thin film piezoelectric resonators with cantilevers connected to electrode fingers;

FIG. 23 shows piezoelectric resonator connected to an impedance matching circuit;

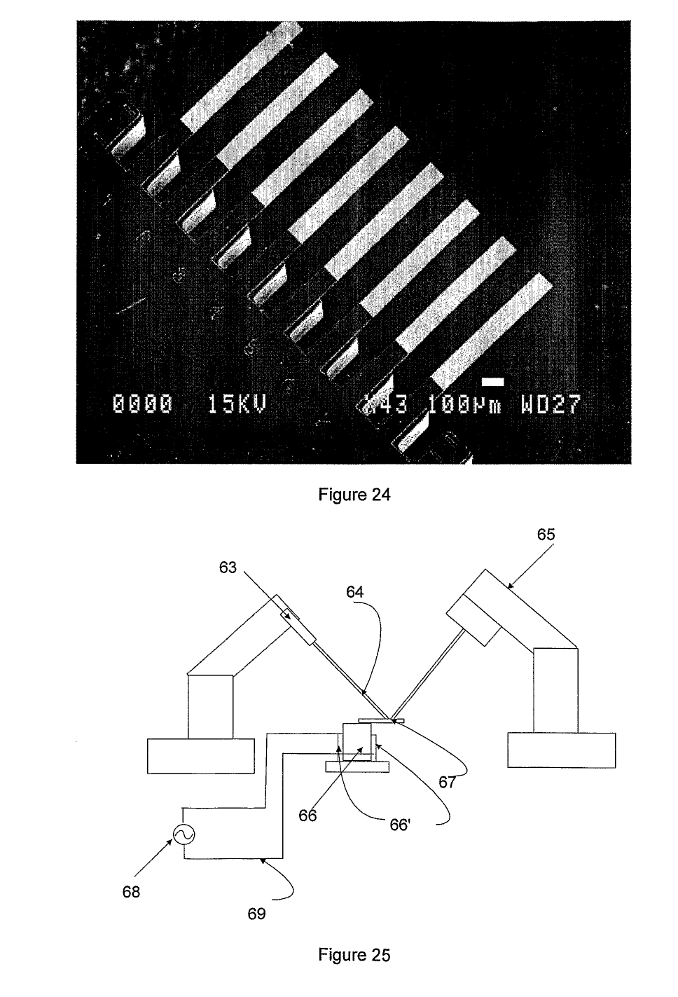

FIG. 24 shows an array of silicon microcantilevers of length 750 μm, width 100 μm and thickness 2 μm.

FIG. 25 shows an optical detection system for the measurement of vibration of microcantilevers mounted over a piezoelectric stack;

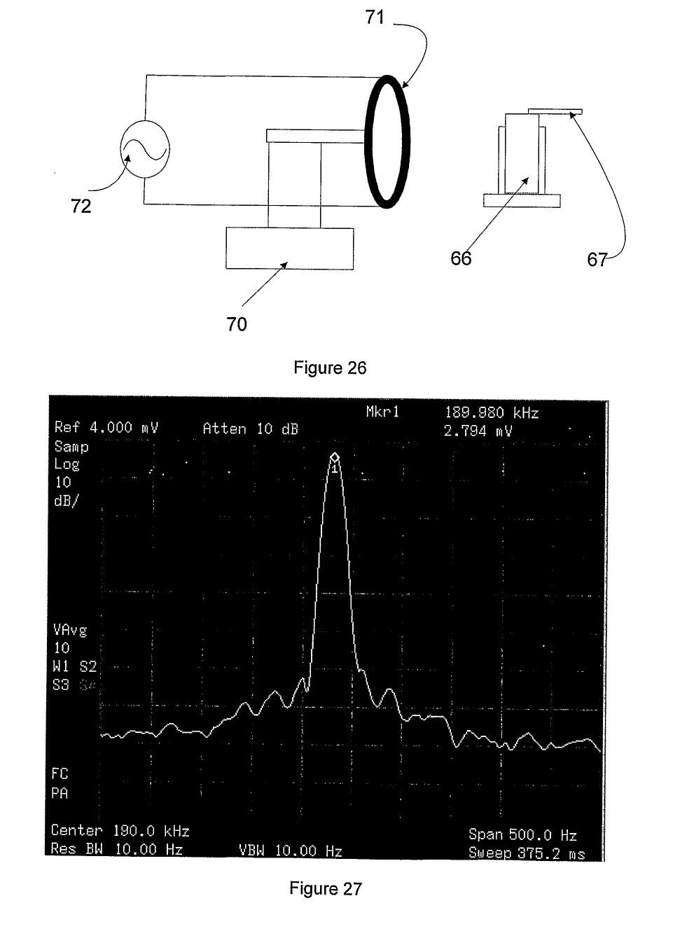

FIG. 26 shows a radio frequency coil connected to a signal source and a set of cantilevers mounted over a piezoelectric stack;

FIG. 27 shows the response of wired radio frequency excitation applied to a piezoelectric-microcantilever system;

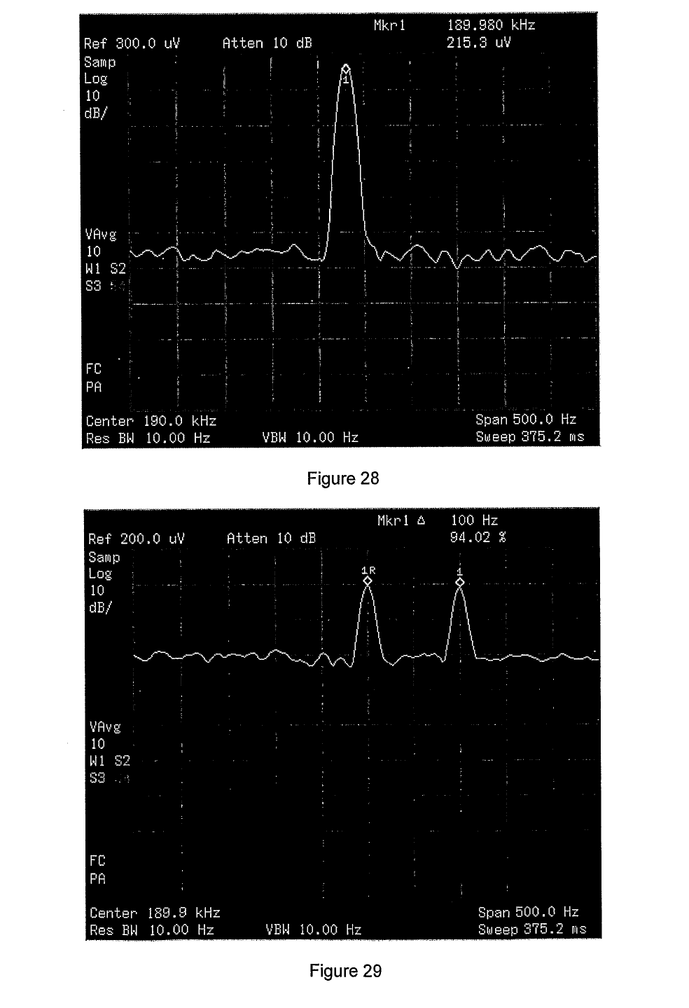

FIG. 28 shows the response of wireless radio frequency excitation applied to a piezoelectric-microcantilever system;

FIG. 29 shows the process of beats formation because of the superposition of wired and wireless RF excitations;

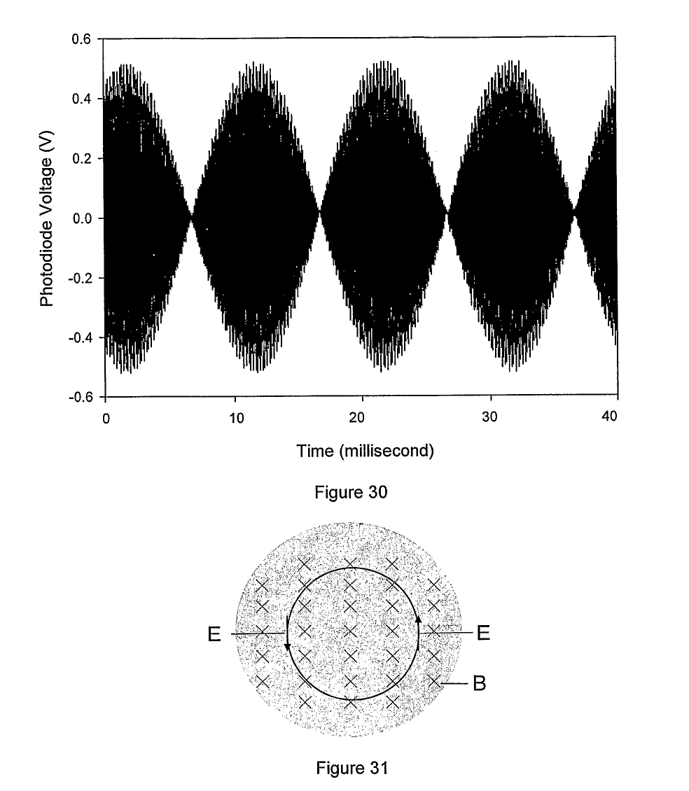

FIG. 30 shows the process of beats formation because of the superposition of wired and wireless RF excitations in time domain;

FIG. 31 shows induced electric fields within a region of time varying magnetic field. The cross signs indicate magnetic field going into the paper at a certain instant of time;

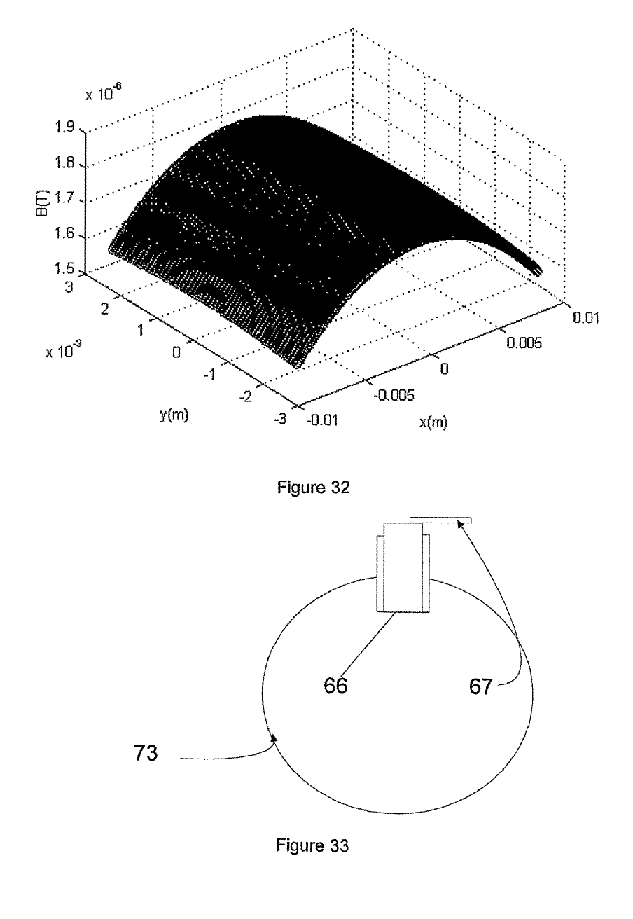

FIG. 32 shows the magnetic flux density of an RF coil over an area of a piezoelectric stack;

FIG. 33 shows a microcantilever mounted over a piezoelectric stack with a wire connected to the piezoelectric stack to form a loop;

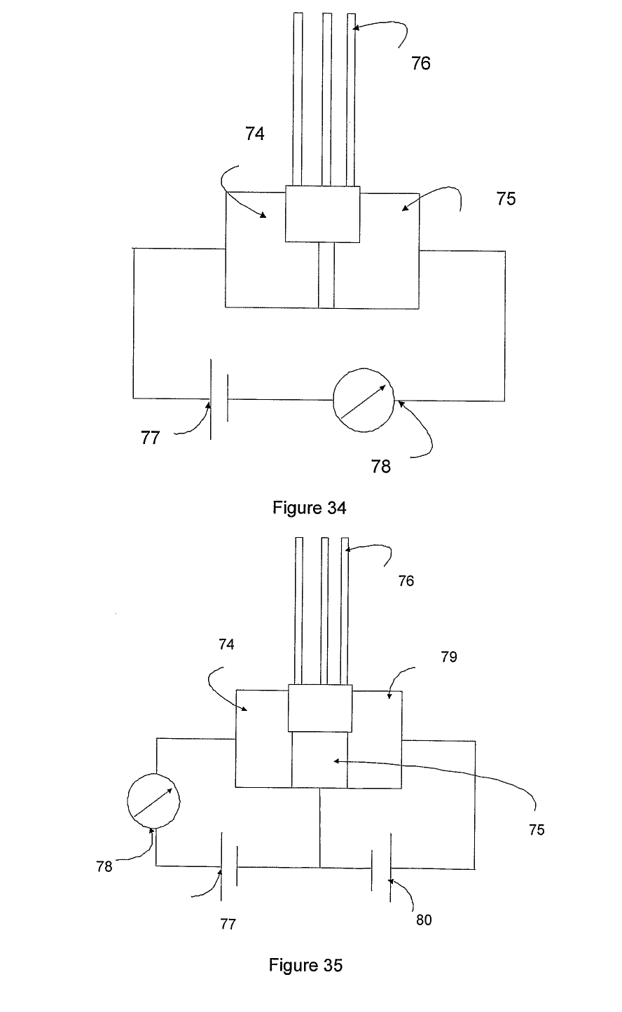

FIG. 34 shows a microcantilever mounted over a p-n junction diode; and

FIG. 35 shows a microcantilever mounted over a pnp bipolar junction transistor.

### DETAILED DESCRIPTION

The present invention relates to an ultra small antenna using piezoelectric materials. A thin film or bulk form of piezoelectric material provides a medium where the wavelength of the applied radio signal is shortened as it propagates through it. Time-varying wired electrical excitation results in acceleration of charges within the material which eventually results in electromagnetic radiation from the material. When electromagnetic waves propagating through free space hit a piezoelectric material, the electrical charges within the material are accelerated resulting in a flow of current and generation of voltages in the material and it acts as a receiving antenna. The high quality factors associated with resonant modes of the piezoelectric crystals imply that they can be used in place of normal antennas as transmitter and receivers of electromagnetic waves for telecommunication and related applications. The high quality factor associated with microstructure's vibrations results in selective filtering of low power signals in a noisy environment.

A piezoelectric material is electrically polarised under the application of a static electric field. This leads to mechanical deflection within the material and stress. When an alternating electric field is applied to a piezoelectric material, bulk and surface mechanical waves (or elastic waves) are set up in the material due to a change in the direction of electrical polarisation and the direction of mechanical stresses associated with it. These waves are also called Rayleigh-Lamb waves. These waves can have frequencies up to tens of GHz. The acceleration of charges in the material associated with time varying electrical excitation leads to radiation of electromagnetic waves in space. The surface and bulk mechanical waves enhance the acceleration of charges within the material leading to an enhanced emission of electromagnetic radiation in free space because of interplay between the electrical and mechanical forces.

The elastic or mechanical waves within the piezoelectric material can have forms different from Rayleigh-Lamb waves. They could also be Love waves or horizontally polarized shear waves. Depending on the excitation these elastic waves can also take the form of primary wave (P-wave) or secondary or shear waves (s-wave). The amplitude of vibration of the piezoelectric material and the transmitted electromagnetic wave become high under a resonance between its surface or bulk mechanical modes and the modes of the wired or wireless time-varying electrical excitation applied to it. As the quality factor of piezoelectric crystals can be very high, a very efficient transmitting antenna can be developed using such crystals.

In a brief overview of a first embodiment of the present invention, there is shown in FIG. 1 a piezoelectric system. The piezoelectric system 100 comprises a piece of piezoelectric material 1 with electrodes 2 and 3 connected to a voltage source 4 for wired electrical excitation. Application of a time varying voltage to the electrodes 2 and 3 would result in an electric field across the material 1, which would lead to generation of mechanical waves within the piezoelectric material 1. For low frequency electric fields (<10 KHz), the charges within the piezoelectric material 1 are accelerated and there is a displacement current between the electrodes. This leads to generation of electromagnetic waves. The physics of the system 100 undergoes some change when the frequency of excitation is raised to a relatively higher value.

The variation of electrical polarisation with mechanical stress in a piezoelectric material 1 can be defined as the piezoelectric strain constant of the device. Thus,

$${( \frac{\partial P}{\partial S} )}_{E} = - δ$$

where P is the polarisation and S is the mechanical stress. The unit of δ is metre/volt and it is the primary physical quantity of interest in terms of selection of a piezoelectric material for sensor based applications. Each type of p-material 1 has a unique piezoelectric strain constant that allows calculation of physical distortion upon the application of a potential. A typical value of piezoelectric strain constant could be 1 nm/volt. Hundreds of layers of such piezoelectric material can augment the net displacement. The total displacement of such a stacked structure can be defined as:

d=nδV

where d is deflection, n is the number of layers and δV is the voltage applied across the top and the bottom layers of the piezoelectric stack. The displacement changes its direction with the polarity of the applied voltage. This is because of a lack of a centre of symmetry in the molecular structure of a piezoelectric material as shown in FIG. 3, where an application of compressive force in the horizontal direction results in decrease in the angle θ and development of polarization along the downward direction. A tensile force along the horizontal direction results in an increase in the angle θ and development of polarization along the upward direction.

FIG. 2 shows a sample arrangement of one plane through a piezoelectric crystal as is known in the art. The dashed lines of FIG. 2 show an asymmetrical configuration of charges which is the origin of the piezoelectric phenomenon.

The piezoelectric materials which can be used for transmission and reception of radio signals are quartz, barium titanate (BaTiO₃), lead titanate (PbTiO₃), lead zirconium titanate (Pb[ZrTi]O₃ or PZT), potassium niobate (KNbO₃), lithium niobate (LiNbO₃), aluminium nitride, lithium tantalite (LiTaO₃), zinc oxide (ZnO), silicon, germanium and silicon-germanium (Si—Ge). The dimensions of the devices can be from a few nanometres to a few millimetres and they can be developed by thin film deposition techniques.

One major advantage of use of piezoelectric materials for radio signal reception and transmission is that the wavelength of mechanical waves within the material is much smaller than the wavelength of radio signal. Thus very small antennas can be developed. The operating frequencies of the devices can range from 10 MHz to 10 GHz. With some modification in the material, the frequency can be raised to 100 GHz. Below 10 MHz, the device can work with poor efficiency.

Depending on the set of radio frequency signals which have to be transmitted and received by the system, the resonant frequency of the piezoelectric material can be pre-decided during manufacturing. The wavelength of a mechanical wave within the piezoelectric material is λ=c/f where c is the velocity of the mechanical wave and f the frequency of the wave. After the calculation of wavelength λ within the piezoelectric material the spacing between the electrode fingers can be decided by the equation L=(2n+1)λ/4 or L=nλ/2 (n is an integer) depending on the boundary conditions. The electrode spacing can be correspondingly configured for better efficiency.

FIG. 3a is known in the art and shows the internal structure of a multilayered piezoelectric stack 14 especially designed to raise its strain voltage ratio. Its construction has been described in detail in U.S. Pat. No. 6,462,464. It has a number of piezoelectric layers 5 each having a thickness of several microns all glued together to from a compact piezoelectric stack. Each layer has metallic layers 6 and 7 having a thickness of a few microns deposited on both the sides. There could be a total of 624 such layers on a stack of 18 mm height each of 20 micron thickness with each layer covered by a 2 micron thick metallic layer. There are side metallic layers 8 on the sidewalls of the piezoelectric stack which form as an interface between external wires and the internal piezoelectric material. The thickness of the side metallic layer 8 is around 10 micron which is used to excite all the layers 9 together. The side metallic layers 8 are connected to an internal layer, which is a metallic resin which can be displaced mechanically without causing any stress to the metallic layer.

The metallic leads on the sides of the piezoelectric stack and the plurality of metallic layers on the top and bottom side of the piezoelectric material act as a number of capacitors 10 as shown in FIG. 3a.

FIG. 3b shows a second embodiment of the present invention: a piezoelectric stack 14 having thin layers which are tapered at the ends. This is done to raise the bandwidth of the resonant frequency. Each subsection of the layer having a certain thickness has a certain resonant frequency corresponding to the spacing between the electrodes in the particular layer and by having tapered sections 9, a succession of closely spaced resonant modes can be achieved.

The signal received by the piezoelectric stack 14 can be amplified by mounting a microcantilever 11 on top of the piezoelectric stack as in a third embodiment of the present invention shown in FIG. 3c. The resonant frequencies of the piezoelectric stack 14 and the microcantilever 11 can be different values and may be adjusted to be relatively close or the same. The vibration of the cantilever could be measured by measuring its capacitance change with respect to some ground plane. Alternatively, another thin film of piezoelectric material 11′ could be developed on top of the cantilever which could be linked to one of the electrodes so that there is an additional voltage because of vibrations of cantilevers. The cantilever can be replaced by similar free standing structures.

A piezoelectric material as a receiver is a third embodiment of the present invention shown in FIG. 4. An RF coil 12 excited by a signal generator 13, generates an RF magnetic field which is picked up by the piezoelectric stack 14. The signal can be observed on a spectrum analyser 15. At low frequencies, the system can generate only magnetic fields but as the frequency increases, the electric field of the electromagnetic wave can be easily detected.

An incoming electromagnetic wave interacts with the bound charges of a piezoelectric material. This results in acceleration of the charges and periodic change in the electrical polarisation of the material. This results in the generation of a mechanical wave (Rayleigh-Lamb wave) within the material leading to an enhanced acceleration of charges within the material because of an interplay between electrical and mechanical forces, resulting in an enhanced displacement current which induces a relatively higher degree of voltage in the piezoelectric material.

The amplitude of mechanical modes and electromagnetic modes can be raised when their frequencies match the frequencies of a wireless electromagnetic wave propagating in free space. Thus the system can act as a very good electromagnetic wave receiver or a receiving antenna. If the frequency of the incoming wave is above a certain frequency, the acceleration of the bound charges would lead to a conduction current within the material leading to an enhanced radiation.

A related aspect of the invention is use of a free standing piezoelectric material sandwiched between two electrodes as shown in FIG. 5a. 16 is a semiconductor substrate over which the free standing beam 17 is developed with electrodes 18. The whole structure is supported by the edge of the substrate 16. Under the application of an electric field, the vibrations are generated within the beam 17. This necessitates the development of an air gap which is accomplished by first depositing and patterning an area of support material followed by deposition and patterning of the piezoelectric material along with the electrodes and finally etching the sacrificial material. Wet etching and plasma etching are found to be excellent for the development of resonators. Such devices are called Film Bulk Mechanical Wave (FBAW) resonators. The embodiment of FIG. 5a can be modified to encompass other structures like cantilevers, bridges and related freestanding structures having flexural or torsional modes of vibrations. FIG. 5b shows further embodiment of the present invention where a cantilever where the piezoelectric material 17 is hanging in space free to vibrate.

The experimental set up of FIG. 4 was used to measure the induced voltage in the piezoelectric stack 14 of dimensions 2 mm×5 mm×5 mm placed at a distance of 2 cm from the RF antenna 12 comprising from a 5 turn copper coil of radius 2 cm excited by the signal generator 13. The coil was excited at 48 MHz and 1 V, resulting in a current of 36.72 mA generating a magnetic field of 2.09 μT at a distance of 2 cm along the coil's axis. FIG. 6a shows a signal of amplitude 79.71 mV received by the piezoelectric stack. The voltage measured along the opposite terminal of a coil of such dimension for the given values of magnetic field and frequency using Faraday's law of induction would be 3.2 mV. (The total voltage induced in the coil would be its double i.e. 6.4 mV). The high value of voltage induced in the PZT stack is because of the quality factor of 20 at its resonant frequency of 48 MHz.

The stack of piezoelectric material discussed in earlier figures can be mounted in various configurations. FIG. 8a shows a further embodiment of the present invention where such a layer of piezoelectric material 22 is mounted on a substrate 16 and is excited by the electrode 20 through a voltage source 13. The ground plane could be some layer on the substrate 16 or positioned elsewhere FIG. 8b shows a further embodiment in which an array of piezoelectric rods having varying lengths connected to an electrode 20 like the wires of a Yaggi antenna. Each of the rods has got a different resonant frequency and it can transmit and receive signals of different resonant frequencies. The rods can be like an array or could be arranged along a matrix of 2 or 3 dimensions. FIG. 8c shows a further embodiment of the present invention where the electrode 20 is located within the cross sectional area of the piezoelectric material 23. The piezoelectric material can have cylindrical form as shown in FIG. 9a where the exciting electrode 20 is at the bottom of the cylindrical piezoelectric material 24. FIG. 9a shows an embodiment in which a disc shaped piezoelectric material 24 which is excited by the electrode 20. The discs could be of varying sizes and they can be configured in a matrix. The advantage associated with the discs is the standing wave associated with the curved structure whose bandwidth is different from rod shaped structures. The electrode for the excitation of disc shaped piezoelectric material could be straight as shown in the diagram or curved. The discs shaped piezoelectric material could be in bulk or thin film form. The electrode can be connected along the side as in the additional embodiment of the present invention shown in FIG. 9b or along the cross sectional area as in the additional embodiment of the present invention as shown in FIG. 9c. FIG. 10 shows a further embodiment of the present invention which has a disc shaped piezoelectric material with electrodes connected to the outer and the inner discs. Different piezoelectric materials having various thickness can be integrated together to achieve multimode operations. The different forms of piezoelectric material can result in different radiation patterns and directionality in space.

Planar piezoelectric materials with patched sections having different resonant frequencies will have some additional advantage in terms of choice of advantage associated with the discs is the standing wave associated with the curved structure whose bandwidth is different from rod shaped structures. The electrode for the excitation of disc shaped piezoelectric material could be straight as shown in the diagram or curved. The discs shaped piezoelectric material could be in bulk or thin film form. The electrode can be connected along the side as in the additional embodiment of the present invention shown in FIG. 9b or along the cross sectional area as in the additional embodiment of the present invention as shown in FIG. 9c. FIG. 10 shows a further embodiment of the present invention which has a hollow cylindrical shaped piezoelectric material with electrodes connected to the outer and the inner discs. Different piezoelectric materials having various thickness can be integrated together to achieve multimode operations. The different forms of piezoelectric material can result in different radiation patterns and directionality in space.

Planar piezoelectric materials with patched sections having different resonant frequencies will have some additional advantage in terms of choice of resonant frequencies. FIG. 11a shows one such embodiment of the present invention where two patches 25 and 26 form parts of a plane piezoelectric material 251. The resonant frequency of these sections are different. Electrodes 27 and 28 permit excitation of radio signals in the transmission mode and reception of radio signals in the reception mode. FIG. 11b shows another such embodiment where the patch sections 31 and 32 have different cuts allowing existence of different resonant modes within the same piezoelectric material 251. The electrodes 29 and 30 permit excitation of radio signals. One of the electrodes could be used as ground and the other could be used as the feed terminal. The embodiment shown in FIG. 11c has, besides the patched sections 33 and 34, an additional section 35 which is entirely detached from the rest of the piezoelectric material 251. The system has electrodes 36, 37 and 38 and a ground plane 39 at the base of the substrate 16. FIG. 11d again shows a further embodiment of the present invention of a planar configuration with patched sections 42 and 43 with electrodes 40 and 41. The different patched sections 42, 43, may be made out of different piezoelectric materials as well.

FIG. 12 shows a further embodiment of the present invention of three dimensional configuration of piezoelectric material having a planar structure 47 parallel to another planar section 46. The electrodes 44 and 45 permit excitation of the two sections. Such an embodiment would lead to different radiation patterns in addition to responsiveness to different resonant frequencies.

The results obtained for a stack of piezoelectric material also hold for surface mechanical waves or Rayleigh-Lamb wave based devices with interdigital electrode fingers developed over the piezoelectric surface. FIG. 13a shows a further embodiment of the present invention of one such device where the piezoelectric substrate 50 has electrodes 48 and 49 having fingers which are interleaved and excite surface waves under the application of voltage from a source 51.

The wavelength of a mechanical wave within the piezoelectric material is λ=c/f where c is the velocity of the mechanical wave and f the frequency of the wave. After the calculation of wavelength λ within the piezoelectric material the spacing between the electrode fingers can be decided by the equation L=(2n+1)λ/4 or L=nλ/2 (n is an integer) depending on the boundary conditions. The electrode finger spacing can be correspondingly configured for better efficiency.

Such a device can act as a receiver as shown in FIG. 13b where a resistive load 52 is connected to the SAW based device. The input electromagnetic wave excites mechanical waves on the piezoelectric material, which travel to the other end of the electrodes and develops a voltage.

FIG. 14a shows a signal of voltage 106.9 mV received by a device of dimensions 5 mm×5 mm×0.001 mm generated by a copper coil of 5 number of turns and a radius of 2 cm, placed at a distance of 2 cm from it. The copper coil was excited at 173 MHz and 1V, which resulted in a current of 35.08 mA in it generating a magnetic field of 1.94 μT at a distance of 2 cm along its axis. The voltage measured across the terminals of a coil of similar dimension at this frequency according to the Faraday's law of induction would be 26.4 mV (The calculated voltage across the whole loop would be 52.8 mv). The high value of induced voltage across the electrodes of the SAW device is because of a resonance mode at 173 MHz with a quality factor of 5.

The device can also be used as a transmitter. Under an excitation of 173 MHz and 1V of the same device, the voltage induced in a copper coil of 5 turns and 2 cm radius, placed at a distance of 2 cm from it was measured to be 48.24 mV as shown in FIG. 14b. This proves that these devices can act as excellent transmitting antennas.

FIG. 14c shows the result of a normal multi-turn coil as a transmitter and a receiver. The parasitic effects associated with the coil dominate at higher frequencies resulting in a drop in the response. FIG. 14d shows the response of a thin film resonator and it shows multiple peaks even in the high frequency range.

The devices can have more than one live (48) and ground electrode (49) fingers as shown in a further embodiment of the present invention of FIG. 15a. However, the spacing of the electrode fingers must be as described earlier. In an alternative embodiment, the ground or the live electrode finger can be single or multiple as shown in FIG. 15b. The presence of additional electrode fingers can enhance signal transmission and reception. In the reception mode, the additional electrode fingers can make the waveform substantially smoother. Depending on the varying length of the electrode fingers, a waveform having a particular shape can be generated. This technique of modifying the response of such devices by varying the overlap between adjacent electrode fingers is called apodization.

In a further embodiment of the present invention, the presence of an array of reflector electrodes 51 and 52 as shown in FIG. 15c is essential for enhanced signal transmission and reception. The reflectors 51 and 52 are placed at each side of the electrodes 48, 49 in order to form an electromagnetic standing wave across the electrodes 48, 49. The standing wave formed between the reflector arrays reduces the losses within the system and it raises the quality factor of the system.

A ladder-like configuration of the device is a further embodiment of the present invention as shown in FIG. 16a is essential for an enhanced bandwidth and lower losses. Quite often, thin films of piezoelectric materials have very narrow bandwidths which may limit their performance. The devices can be used in parallel in order to further enhance their performance. This has been shown in FIG. 16b. A parallel arrangement results in an increase in the total surface area which leads to enhanced signal transmission and reception. Instead of having a number of these devices connected together, a number of electrodes could also be developed on the same piezoelectric substrate in order to bring about similar effect. FIG. 16c shows one such device whose pair of electrodes 48 and 49 are arranged horizontally and vertically. Such a device is equally sensitive to vertically as well as horizontally polarized electric field.

The devices could also be stacked on top of each other such that their respective electrodes are interconnected in order to reduce the space requirement and increase performance.

A further embodiment of the present invention involving the convolution of the output of two or more devices is shown in FIG. 17. Such an arrangement may make use of a metal strip 53 connected to the top electrodes 48.

FIG. 18 shows a different embodiment where the mechanical waves are reflected in a ‘z’ manner in order to change the radiation pattern used in some niche applications. In this arrangement, the mechanical waves cover a bigger area of this device.

The length of the electrodes and related fingers also determines the amplitude of the mechanical waves which are generated on the piezoelectric film. FIG. 19 shows an embodiment where the electrode fingers are zigzag-shaped in order to increase the total length. FIG. 20 shows an embodiment featuring spiral electrodes. Another set of spiral electrodes may be embedded close to the device to form a second set.

FIG. 21 shows a further embodiment of the device where the fingers of the electrodes 48 and 49 are slanted and are of tapering width. This configuration of electrode fingers permits widening of the bandwidth of the device. The aperture length of the channel and the spacing of the electrodes can be used to determine the lower and upper cut off frequencies. The details have been described in Reference 1 (“Design Techniques for SAW filters using slanted finger interdigital transducer, Hiromi Yatsuda,” IEEE Transactions on Ultrasonics, Ferroelectrics and Frequency Control, 44, 2, 1997, (453-459)) which exclusively deals with wideband filters but similar methods can be used to develop antennas for wireless applications. To raise the transmission and reception abilities, a number of these devices can be stacked on top of each other and respective live and ground electrodes connected to each other.

FIG. 22 shows a further embodiment of the device where cantilevers 11 are connected to the electrodes 48 and 49 in order to enhance the response of the device as a receiver. The resonant frequency of the cantilevers must correspond to the resonant frequency of the device. The vibration of the cantilevers could be measured by measuring the change it their capacitances or by integrating thin films of piezoelectric materials on top of them and measuring the physical properties of these piezoelectric materials using an electronic circuit or by simply connecting the piezoelectric material to the electrodes. The cantilevers may be made of a piezoelectric material.

The piezoelectric material can be modeled as a sum of resistor, capacitor and an inductor around its resonant frequency. The device acts as a purely resistive circuit at resonance, as a capacitive element with series resistance below its resonant frequency and as an inductive element with some resistance above the resonant frequency. A symbolic circuit diagram for this behaviour, just above its resonant frequency is shown in FIG. 23 where the resistive 61 and inductive 62 elements respectively represent the piezoelectric material. External capacitor 59 is connected in series to the piezoelectric material and external inductor 60 is connected in shunt to the piezoelectric material to match the total impedance of the system to free space. This impedance matching raises the total sensitivity. The values of the circuit elements are taken into account by doing proper calculations as per the prior art in this field. The products of impedances of series and shunt elements (capacitive or inductive) should be equal to the product of impedances of load and the signal generator in the transmission mode and free space in the reception mode. A resonant circuit having very good quality factor can also be used instead of 18 and 19 or along with it.

An alternative way of impedance matching would be to use a section of line of length λ/4, λ where is the wavelength, whose impedance equals the product of load and source impedances. Yet another way of impedance matching would be to make use of the Smith Chart.

Adding a coil to the piezoelectric material would raise the total area, the flux collecting ability and the sensitivity of the system. The sensitivity of the device can also be raised by quality factor improvement. The device can be enclosed in vacuum in order to achieve this. An alternative method would be to compensate the mechanical losses during the vibration by incorporating an electrical circuit applying an electrical signal in response to the resonance frequency and phase of the vibration frequency.

The resonance frequency of the piezoelectric material can be changed by applying a DC bias or by mechanical loading of the device.

The results shown in FIGS. 6a, 6b, 14a and 14b are for transmission and reception for the near field region of an antenna, however, the piezoelectric stacks and thin film devices can receive signals if they are situated in the far field region of an electromagnetic field.

The electromagnetic waves received by a piezoelectric device can be connected to or integrated with the electronic circuit of telecommunication equipment like television, mobile, radio receiving set and computers. The piezoelectric device can also act as transmitter in telecommunication applications. Another interesting application of such devices can be in radio frequency identification tags.

As surface or bulk mechanical wave devices are widely used as filters in telecommunication applications, the present device can be used simultaneously as an antenna and a filter.

One of the greatest problems associated with conventional antennas is poor sensitivity. In a wireless communication link, radio signals are obstructed by physical objects, which causes scattering of the wavefront. This can cause a reduction in data speed and an increase in the number of errors. The use of antenna arrays in order to locate the spatial signature of signals (viz. Directional Arrival of Signal) and construction of radiation pattern by constructive addition of the phases, can reduce or eliminate the trouble caused by multipath wave propagation. These are called Smart antennas, adaptive array antennas or Multiple Input Multiple Output antennas. They have an additional use in the field of software defined radio integration which enable efficient use of channels and available bandwidth.

Unfortunately, smart Antennas are plagued by several problems like the need of an array of antennas for isotropic signal reception. The big size of conventional antennas implies that use of smart antennas will be confined to a certain niche market only. We need ultra-small antennas to be able to bring about a significant transformation in the field of smart antennas. Because of piezoelectric devices, ultra-small antennas may be used in smart antennas.

The device may further comprise an array of free standing microstructures which can be microcantilevers, microbeams, membranes or any related structure which can mechanically vibrate by the virtue of having some fixed end(s) and some free end(s). The vibrations may be longitudinal, axial, torsional or flexural. A microcantilever is a representative of such a free standing microstructure. The scanning electron microscopy image of such an array of microcantilever developed using deep reactive ion etching have been shown in FIG. 24 as the principle sensing element. The microcantilevers are mounted on a piezoelectric material and the deflection of the microcantilevers is measured by shining a laser beam on the array and allowing the reflected light to fall on a quadrant photodetector. This has been shown in FIG. 25 where the microcantilevers 67 are mounted over a piezoelectric stack 66 which is connected to a radio signal source 68 through its metallic leads 66′ and the connecting wires 69. The laser diode 63 generates a beam 64 which falls on the tip of microcantilevers 67 and the reflected beam is allowed to fall on a photodetector 65. The microcantilevers are mechanically excited by wired radio frequency electrical excitation from a signal source 68 which is connected to the metallic leads 66′ of the piezoelectric stack 67 through the wire 68. Any vibration of the microcantilever tip 67 is transformed into an electrical signal, which can be read on an oscilloscope or a spectrum analyser connected to the photodetector 65.

FIG. 26 shows a radio frequency coil 71 mounted on a stand 70 excited by a signal generator 72. The coil, under wired electrical excitation by 72, generates radio frequency magnetic fields and is placed close to the piezoelectric-microcantilever system without being physically connected to it.

When the wired radio frequency electrical excitation applied to the microcantilevers through the piezoelectric stack matches the mechanical resonance frequency of the microcantilevers, a peak corresponding to high amplitude vibration of the microcantilever is observed on the oscilloscope. The Fourier Transform of such a signal has been shown in FIG. 27 where the rms value of the output voltage is close to 2.794 mv at a frequency of 189.98 KHz. In the present case, the principle resonant signals were found at 189.98 KHz, 482.7 KHz and 596.4 KHz.

With the wired radio frequency electrical excitation to the piezoelectric stack 66 switched off, as the wireless radio frequency magnetic excitation through the coil 71 of FIG. 26 is switched on by exciting it using the signal generator 10, the vibration of the microcantilevers 67 go high at resonance. FIG. 28 shows the photodetector signal with a root mean square amplitude of 215.3 μV.

The piezoelectric-microcantilever system is excited by the magnetic field component of the electromagnetic wave. In the near field region of an RF coil, the magnetic field is strong and more dominant than the electric field. The system does not respond to the electric field component in any way. When the piezoelectric-microcantilever system is excited simultaneously by wired and wireless excitations, as the radio signal frequency of the wireless source approaches the resonance frequency of the microcantilever, beats are formed due to the superposition of wired and wireless electrical excitations on the piezoelectric-microcantilever system. The frequency of the beats decrease as the signal frequency comes closer to the resonance frequency of the microcantilever. The beats have been shown in FIG. 29. In this case, wired radio excitation to the piezoelectric material was maintained at 189.88 KHz and 1 mv volt and the radio frequency signal source connected to the coil 9 was excited at 290.98 KHz and 1V. The frequency of the beats changed depending on the difference between the frequencies. A spectrum analyser showed two closely spaced Fourier components. FIG. 30 shows one such beats in time domain. It corresponds to a different set of piezoelectric-microcantilever system. The magnetic field of a loop of radius a, number of turns N, current I at a distance r is given by

$$B = {μ}_{0} N \frac{{a}^{2} I}{2 {( {a}^{2} + {r}^{2} )}^{3 / 2}}$$

(μ₀ is the permeability of the medium).

For an RF excitation at a frequency of 189.88 KHz and an amplitude of 1V applied to the coil of radius, a=2 cm, the current developed is I=36.093 mA and magnetic field at a distance of r=2 cm is B=2.00 μT. At a frequency of 189.98 KHz, voltage developed across the stacks of dimension 5 mm−5 mm−2 mm is 23.94 μV. The total voltage drop across the leads which are on the opposite sides of the piezoelectric stack is half of it i.e. 11.97 μV. This means that the radio frequency loop excited by 1V results in an application of 11.97 μV across the piezoelectric stack. This creates a photodetector signal of 215.9 μV. The ratio between the excitation signal and the photodetector signal is 1:18.03. This ratio can be called R_{wireless}.

Measurements for wired RF excitation to the piezoelectric stack at 189.88 KHz indicate that 1 V of wired piezoelectric excitation creates a 186.8 μV across the piezoelectric stack resulting in photodetector signal of 2.794 mV. Thus the photodetector signal per unit excitation voltage is 1 V. Thus the ratio between piezoelectric voltage under wired excitation and the photodetector signal is 1:14.95 which is nearly the same for wired and wireless RF excitations. We can term this ratio as R_{wired}.

FIG. 31 shows the circulating electric fields associated with time varying magnetic field at a certain instant of time when the magnetic flux lines are penetrating the page. The induced voltage is developed because of the circulating electric fields.

When the magnetic flux density is non-uniform, the wireless excitation brings about a higher degree of response i.e. the numerical value of R_{wireless} is much higher than R_{wired}. When the dimensions of one face of a piezoelectric stack is 18 mm−5 mm, the magnetic flux density generated by a coil of radius 2 cm carrying a current of 32 mA at a distance of 2 cm is non uniform over its area as shown in FIG. 32. The ratio between R_{wireless} and R_{wired} was measured to be high as 27 for some frequencies. It acquired higher values with an increase in frequencies. This observation remains inexplicable and needs further investigation.

The sensitivity of the device can be raised by connecting a loop in the piezoelectric stack as shown in FIG. 33. The loop 73 increases the total area raising the value of total flux associated with the system which results in an increase in voltage induced within the piezoelectric material. In this case, the signal level under wireless excitation can be higher by a factor of 10 to 50 depending on the size of the coil. When the size of the coil is bigger, increasing the total effective area of the piezoelectric stack provides an additional leverage in terms of sensitivity.

Other techniques of improvement of sensitivity are by raising the quality factor by proper use of vacuum. Use of electrical circuits which can compensate the loss of damping linked to microcantilever vibrations by providing cyclic energy to the system can also be used to raise the quality factor.

The optical detection method described in FIG. 25 can be replaced by another system as shown in FIG. 34 where the cantilevers 76 are mounted over a diode with a p-type semiconductor material 74 connected to an n-type semiconductor material 75. The diode is biased by a voltage source 77. Vibrations of the microcantilever will result in a modulation in the diode current which can be measured by an ammeter 78 connected to the system. The diode can be replaced by a bipolar junction transistor with n-, p- and n-type regions as shown in FIG. 35 where an additional n-type region 79 is present besides 74 and 75.

It will be appreciated that although only one particular embodiment of the invention has been described in detail, various modifications and improvements can be made by a person skilled in the art without departing from the spirit and scope of the present invention.

1. (canceled)

2. (canceled)

3. (canceled)

4. (canceled)

5. (canceled)

6. A device as claimed in claim 55, wherein the frequency ranges from 10-MHz to 100 GHz.

7. (canceled)

8. (canceled)

9. A device as claimed in claim 55, further comprising metallic electrodes on a top and bottom surface of the piezoelectric material for electrical excitation in a transmission mode and collection of voltage in a reception mode.

10. A device as claimed in claim 9, wherein said metallic electrodes comprise metallic electrode fingers having spacing L related to wavelength λ of mechanical wave by one of the relations L=nλ/2 and L=(2n+1)λ/4, where n is a positive integer.

11. A device as claimed in claim 9, further comprising a pair of reflector electrodes positioned on opposing sides of said metallic electrodes at a distance sympathetic to a resonant frequency of the piezoelectric material, said distance being selected to ensure the presence of a standing wave between the reflector electrodes and across the metallic electrodes.

12. (canceled)

13. (canceled)

14. A device as claimed in claim 55, wherein the piezoelectric material is developed over a substrate and is isolated from the substrate with a reflector array composed of layers having quarter wavelength thickness.

15. A device as claimed in claim 55, wherein the piezoelectric material has a shape selected from rectangular, triangular, cylindrical and spherical shapes and an electrode is connected to the piezoelectric material at a point selected from along its sides and within its cross sectional area.

16. A device as claimed in claim 55, wherein the piezoelectric material has a planar structure comprising various patches cut into geometrical patterns adapted to create different resonant modes, each patch being provided with a metallic electrode.

17. A device as claimed in claim 55, wherein the piezoelectric material has a three dimensional structure comprising planar arms cut into geometrical patterns, such planar arms and geometric patterns being adapted to create a range of different resonant modes, each planar arm being provided with metallic electrodes, and the whole structure being adapted to create a range of different radiation patterns.

18. A device as claimed in claim 55, wherein the piezoelectric material is provided with interleaved metallic electrodes comprising respective electrode fingers each alternately connected to positive and negative terminals of a voltage source for, in a transmitting mode, application of wired voltage excitation resulting in acceleration of electrons and generation of surface mechanical waves (Rayleigh-Lamb wave) and subsequent electromagnetic radiation, and for, in a receiving mode, collection of induced voltages caused by electron acceleration and generation of surface mechanical waves (Rayleigh-Lamb waves) from an incoming electromagnetic wave.

19. A device as claimed in claim 18, wherein a resonant frequency of the piezoelectric material is matched to a set of radio signals by spacing the electrode fingers by an integral multiple of half wavelengths or an odd integral multiple of quarter wavelengths of a mechanical wave in the piezoelectric material.

20. (canceled)

21. (canceled)

22. A device as claimed in claim 18, wherein live and ground electrode fingers of the device are free standing

23. (canceled)

24. A device as claimed in claim 19, wherein live and ground electrodes and electrode fingers of the device are at least partially buried within the piezoelectric material, the device thus being adapted to generate a mix of surface and bulk waves in the piezoelectric material.

25. (canceled)

26. (canceled)

27. (canceled)

28. (canceled)

29. A device as claimed in claim 18, wherein electrode fingers of the device are of tapering width and are slanted at an angle adapted to enable excitation of other resonant modes and raise the bandwidth of the device.

30. A device as claimed in claim 55, wherein a free-standing structure is mounted on top of the piezoelectric material, said free-standing structure being adapted to mechanically amplify vibrations within the piezoelectric material.

31. (canceled)

32. (canceled)

33. (canceled)

34. (canceled)

35. (canceled)

36. (canceled)

37. A device as claimed in claim 55, wherein a metallic loop is so connected to the piezoelectric material as to raise a total area of electric flux linkage and hence a sensitivity of the device.

38. (canceled)

39. (canceled)

40. A device as claimed in claim 55, wherein an impedance of the piezoelectric material is matched to impedance of one of free space and a signal generator by a section of line of length λ/4, where λ is a wavelength of a mechanical wave in the piezoelectric material, such that an impedance of said section of line equals the square root of the product of the piezoelectric material impedance and the impedance of a respective one of the signal generator and free space.

41. (canceled)

42. (canceled)

43. A device as claimed in claim 55, wherein the piezoelectric material is connected to an electronic circuit in a feedback loop, in which such feedback loop feeds in electrical energy to the piezoelectric material, such energy being matched to a phase and frequency of the piezoelectric material in order to compensate a loss of damping associated with vibrations of the piezoelectric material.

44. (canceled)

45. A device as claimed in claim 55, wherein the piezoelectric material comprises a material selected from quartz, barium titanate (BaTiO₃), lead titanate (PbTiO₃), lead zirconium titanate (Pb[ZrTi]O₃ alias PZT), potassium niobate (KNbO₃), lithium niobate (LiNbO₃), aluminium nitride (AlN), lithium tantalite (LiTaO₃), zinc oxide (ZnO), gallium arsenide (GaAs), silicon (Si), germanium (Ge) or silicon-germanium (Si—Ge).

46. (canceled)

47. (canceled)

48. (canceled)

49. A method of reception of electromagnetic waves by an antenna comprising a thin film of piezoelectric material, wherein an impedance of the piezoelectric material is matched to an impedance of free space by an impedance matching circuit comprising a set of inductors selected from shunt and series inductors and a set of capacitors selected from shunt and series capacitors so connected that products of the impedances of free space and the piezoelectric material match the products of the impedances of said capacitors and inductors.

50. (canceled)

51. (canceled)

52. (canceled)

53. (canceled)

54. (canceled)

55. A device for use as an antenna in a wireless telecommunications network, comprising a thin film of piezoelectric material and adapted to be excited at a frequency greater than 10 MHz.

56. A device as claimed in claim 55, adapted for use as a transmitting antenna, application of a time-varying electrical excitation to the piezoelectric material thereof at a frequency greater than 10 MHz causing emission of radio waves into free space at said frequency.

57. A device as claimed in claim 55, adapted for use as a receiving antenna, application of a radio wave in free space to the piezoelectric material thereof at a frequency greater than 10 MHz causing an electrical excitation in the piezoelectric material at said frequency.

58. A device as claimed in claim 55, comprising a plurality of antennas connected in a configuration selected from series, series-shunt, ladder-like, parallel spaced horizontally and parallel stacked vertically configurations.

59. A device as claimed in claim 55, so adapted that the resonant frequency of the piezoelectric material is changeable by one of applying a static voltage to the piezoelectric material and mechanically loading the piezoelectric material.

60. A communication device provided with an antenna comprising a thin film of a piezoelectric material and adapted to be excited by at least one of application to the piezoelectric material of a time-varying electrical excitation, and application of a radio wave in free space to the piezoelectric material, at a frequency greater than 10 MHz.
